(19) United States
(12) Patent Application Publication
(10) Pub. No.: US 2026/0239592 A1
(43) Pub. Date: Aug. 13, 2026

(54) CABLE AND CABLE MANUFACTURING METHOD

(71) Applicant: SONY SEMICONDUCTOR SOLUTIONS CORPORATION, KANAGAWA (JP)

(72) Inventors: YOSHITAKA YOSHINO, KANAGAWA (JP); MAKOTO MAKISHIMA, KANAGAWA (JP)

(21) Appl. No.: 19/153,232

(22) PCT Filed: Jan. 31, 2024
(86) PCT No.: PCT/JP2024/002978

§ 371 Date: Aug. 1, 2025

(30) Foreign Application Priority Data
Feb. 20, 2023 (JP) 2023-024251

(51) Int. Cl. H05K 9/00

(52) U.S. Cl. CPC H05K 9/0098; H05K 9/0088

(57) ABSTRACT

A cable according to an embodiment of the present technology includes a transmission portion, a magnetic tape, and a magnetic resin layer. The transmission portion includes at least one transmission line that transmits a signal or power. The magnetic tape includes a magnetic layer that absorbs radio waves, and is wound around the transmission portion. The magnetic resin layer is formed of a magnetic resin that absorbs radio waves, and covers the magnetic tape.

### TECHNICAL FIELD

The present technology relates to a cable for transmitting signals or power and a cable manufacturing method.

### BACKGROUND ART

A cable that transmits signals and power may become a path for transmitting electromagnetic noise (hereinafter, will be referred to as noise). For example, a case where noise generated in an apparatus to which the cable is connected enters the cable, or a case where the cable acts as a reception antenna, and noise caused by radio waves enters the cable is conceivable. Also, for example, the cable may act as a transmission antenna, and radio waves that become the noise may be radiated from the cable.

As a countermeasure for such noise, there is a method of improving shield performance of a cable to prevent the cable from being affected by the noise. For example, a method of multiplexing a braided shield surrounding a signal line of a cable and a method of winding an aluminum shield tape over the braided shield are known. These methods have generally been effective against electric field noise, but have been insufficient in the effect of reducing magnetic field noise. For this reason, a noise suppression cable that uses a magnetic material and is effective against both the electric field noise and the magnetic field noise is being developed.

For example, Patent Literature 1 describes a cable provided with a resin layer containing a magnetic material. In this cable, a first shield portion that includes a braided wire is provided around a signal transmission line covered by an insulator. A first layer and a second layer formed of a magnetic powder mixed resin are formed around the first shield portion while a second shield portion that includes an aluminum sheet is interposed therebetween. Of these, the first layer functions as a magnetic shield which suppresses noise flowing through the first shield portion. In addition, the second shield portion reflects an electric field component of the noise that propagates through space, and the second layer suppresses a magnetic field component of the noise that propagates through the space (paragraphs to and in the specification of Patent Literature 1, FIGS. 7 and 8, and the like).

### CITATION LIST

### Patent Literature

Patent Literature 1: WO 2021/060075

### DISCLOSURE OF INVENTION

### Technical Problem

In a resin containing a magnetic material such as the magnetic powder mixed resin described in Patent Literature 1, the magnetic material is dispersed within the resin, thus making it difficult to achieve high magnetic permeability. Therefore, there is a fear that an effect of reducing noise intrusion and radiation cannot be fully exerted.

In contrast, there is also known a method that uses a magnetic tape in the cable. By providing the magnetic material on a tape surface without dispersion, the magnetic tape can achieve high magnetic permeability. Meanwhile, in the cable wound with the magnetic tape, a gap or the like may be generated when the cable is bent, and noise suppression performance may thus be lowered.

In view of the circumstances as described above, the present technology aims at providing a cable that suppresses noise intrusion and radiation and is less likely to deteriorate in performance even when bent, and a cable manufacturing method.

### Solution to Problem

To attain the object described above, a cable according to an embodiment of the present technology includes a transmission portion, a magnetic tape, and a magnetic resin layer.

The transmission portion includes at least one transmission line that transmits a signal or power.

The magnetic tape includes a magnetic layer that absorbs radio waves, and is wound around the transmission portion.

The magnetic resin layer is formed of a magnetic resin that absorbs radio waves, and covers the magnetic tape.

In this cable, the magnetic tape wound around the transmission portion is covered by the magnetic resin layer.

Accordingly, noise intrusion and radiation are effectively reduced by the magnetic tape having relatively high magnetic permeability. Furthermore, by covering the magnetic tape with the magnetic resin layer, shield performance is maintained even when a gap or the like is generated in the magnetic tape due to bending or the like. As a result, it is possible to realize a cable that suppresses noise intrusion and radiation and in which performance is less likely to deteriorate even when bent.

The magnetic tape may include a tape base material on which the magnetic layer is formed. In this case, the magnetic layer may be formed on one of two sides of the tape base material or both of the two sides.

The magnetic layer may be formed on at least one of the two sides of the tape base material that faces an outer side of the magnetic tape.

The tape base material may be a resin tape formed of a polyester-based resin or a polyolefin-based resin.

The tape base material may be a resin tape in which a metal layer formed of one of aluminum, copper, and iron is formed.

The tape base material may be a metal tape that includes a metal foil formed of one of aluminum, copper, and iron.

The magnetic layer may be a coating layer of a magnetic material that is applied on a surface of the tape base material such that the magnetic material is oriented.

The magnetic layer may be a deposited film of a magnetic material or a sputtered film of the magnetic material, the deposited film or sputtered film being formed on a surface of the tape base material.

The magnetic tape may be wound transversely around the transmission portion.

The magnetic tape may be wound transversely around the transmission portion such that parts of the magnetic tape overlap in a width direction.

The transmission portion may include a shield layer surrounding the at least one transmission line. In this case, the magnetic tape may be wound around the shield layer.

The magnetic tape may include an adhesive layer formed on a side of the magnetic tape that faces the transmission portion.

The magnetic layer may contain a magnetic material that includes at least one of iron powder, ferrite powder, or carbon powder.

The magnetic resin may include a synthetic resin that is a base material, and a magnetic material that includes at least one of iron powder, ferrite powder, or carbon powder.

The magnetic resin may contain the iron powder or the ferrite powder. In this case, a proportion of the iron powder or ferrite powder contained in the magnetic resin may be 70% or more and 90% or less by weight in the magnetic resin.

The cable may further include an insulating outer cover layer that covers a circumference of the magnetic resin layer.

The cable may be one of a coaxial cable, a USB cable, a signal cable, a power cable, and an in-vehicle cable.

A cable manufacturing method according to an embodiment of the present technology includes forming a transmission portion including at least one transmission line that transmits a signal or power;

winding, around the transmission portion, a magnetic tape including a magnetic layer that absorbs radio waves; and

forming a magnetic resin layer by applying, onto the magnetic tape, a magnetic resin that absorbs radio waves.

The magnetic resin layer may be a resin coating formed by extruding the magnetic resin onto an intermediate body obtained by winding the magnetic tape around the transmission portion.

### BRIEF DESCRIPTION OF DRAWINGS

FIG. 1 is a graph for explaining a near field and a far field.

FIG. 2 is a graph showing a magnitude of an electromagnetic field in the near field.

FIG. 3A is a schematic cross-sectional view showing a configuration example of a cable according to the present embodiment.

FIG. 3B is a schematic side view showing the configuration example of the cable according to the present embodiment.

FIG. 4 is a schematic diagram showing a configuration example of a magnetic tape.

FIG. 5 is a schematic diagram showing a configuration example of a magnetic layer.

FIG. 6 is a schematic cross-sectional view showing the configuration example of the cable shown in FIGS. 3A and 3B.

FIG. 7 is a schematic diagram showing a configuration example of a magnetic resin.

FIG. 8 is a flowchart showing an example of a cable manufacturing method.

FIG. 9 is a schematic diagram for explaining the steps for manufacturing the cable.

FIG. 10A is a schematic diagram for explaining a configuration of a comparison cable.

FIG. 10B is a schematic diagram for explaining the configuration of the comparison cable.

FIG. 11A is a schematic diagram showing an example of an emission measurement.

FIG. 11B is a schematic diagram showing an example of the emission measurement.

FIG. 12 is a set of graphs showing measurement results of the emission measurement.

FIG. 13 is a set of graphs showing measurement results of the emission measurement.

FIG. 14A is a schematic diagram showing an example of an immunity measurement.

FIG. 14B is a schematic diagram showing an example of an immunity measurement.

FIG. 15 is a set of graphs showing measurement results of the immunity measurement.

FIG. 16 is a set of graphs showing measurement results of the immunity measurement.

FIG. 17 is a schematic diagram showing another configuration example of the magnetic tape.

FIG. 18 is a schematic diagram showing another configuration example of the magnetic tape.

FIG. 19 is a cross-sectional view of a USB 2.0 cable.

FIG. 20 is a cross-sectional view of a USB 3.0 cable.

FIG. 21 is a cross-sectional view of an Ethernet cable.

FIG. 22 is a cross-sectional view of a duplex cable.

### MODES FOR CARRYING OUT THE INVENTION

Hereinafter, embodiments according to the present technology will be described with reference to the drawings. [Near field and far field]

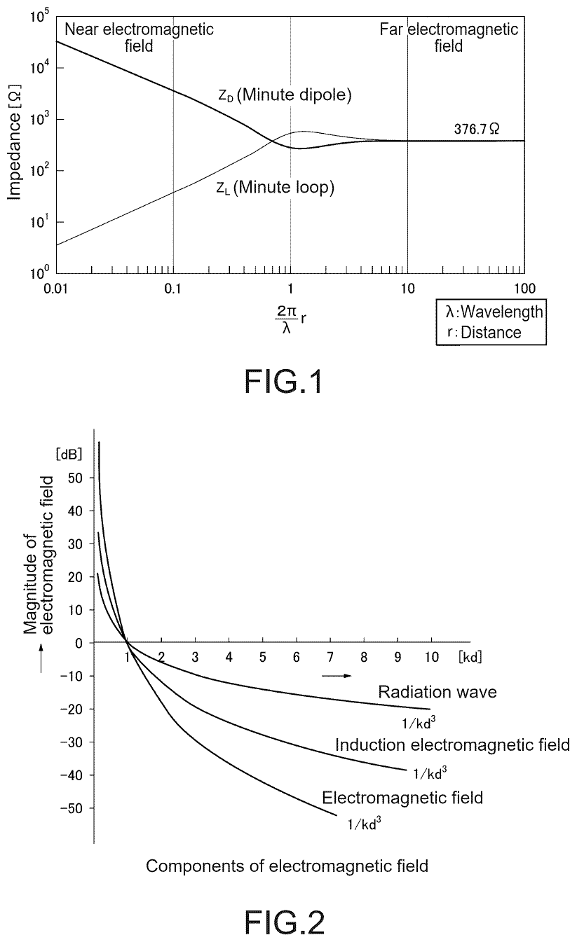

FIG. 1 is a graph for explaining a near field and a far field. Herein, characteristics of an electromagnetic field generated by an antenna will be described. For example, when using an electromagnetic shield near an antenna, an effect of the shield varies according to a wave impedance. Herein, the wave impedance is a ratio (E/H) between an electric field (E) and a magnetic field (H) at a certain location.

FIG. 1 is a graph showing a change of the wave impedance with respect to a distance from the antenna, the graph showing a change of the wave impedance of a minute dipole antenna and a minute loop antenna. Near the dipole antenna, the wave impedance is high because of the strong electric field. On the other hand, near the loop antenna, the wave impedance is low because of the strong magnetic field. When the distance exceeds λ (wavelength of electromagnetic field)/(2π), both antennas converge to a predetermined value (376.7Ω). Conventionally, the field up to this λ/(2π) is called the near field, and the field further than that is called the far field.

In FIG. 1, the distance r is normalized by λ/(2π). 1 on the horizontal axis corresponds to (r=λ/(2π), and this distance is a boundary between the near field and the far field. For example, in a case of 100 MHz, the boundary distance becomes r=0.48 m, (0.1) becomes (r=4.8 cm), and (10) becomes (r=4.8 m). Similarly, a case of 200 MHz results in (1: r=0.24 m), (0.1: r=2.4 cm), and (10: r=2.4 m). Furthermore, a case of 500 MHz results in (1: r=0.095 m), (0.1: r=0.95 cm), and (10: r=0.95 m).

FIG. 2 is a graph showing a magnitude of the electromagnetic field in the near field. The graph of FIG. 2 shows intensities of the electromagnetic field, an induction electromagnetic field, and a radiation wave with respect to the horizontal axis (λ/(2π)). As can be seen from the graph of FIG. 2, the electromagnetic field is quite large in the near field, so shielding becomes necessary as a countermeasure for noise. To eliminate an influence of noise, it is necessary to reduce influences of conductive noise that is transmitted through the cable and spatial noise that enters the cable.

In general, an electric field component of noise can be reduced relatively easily by using a conductor shield that uses a braided wire or the like. On the other hand, since a magnetic field component of noise has a low impedance in the near field, there has been a problem that it is difficult to eliminate the magnetic field component. For this reason, a reduction effect using the conductor shield has not been that large for the magnetic field noise.

The present technology provides a cable that suppresses influences of both the magnetic field noise and the electric field noise described above. The present technology also suppresses noise that enters the cable (spatial noise and conductive noise) as well as noise that is radiated from the cable (spatial noise). Hereinafter, an embodiment of a cable to which the present technology is applied will be described. [Configuration of cable]

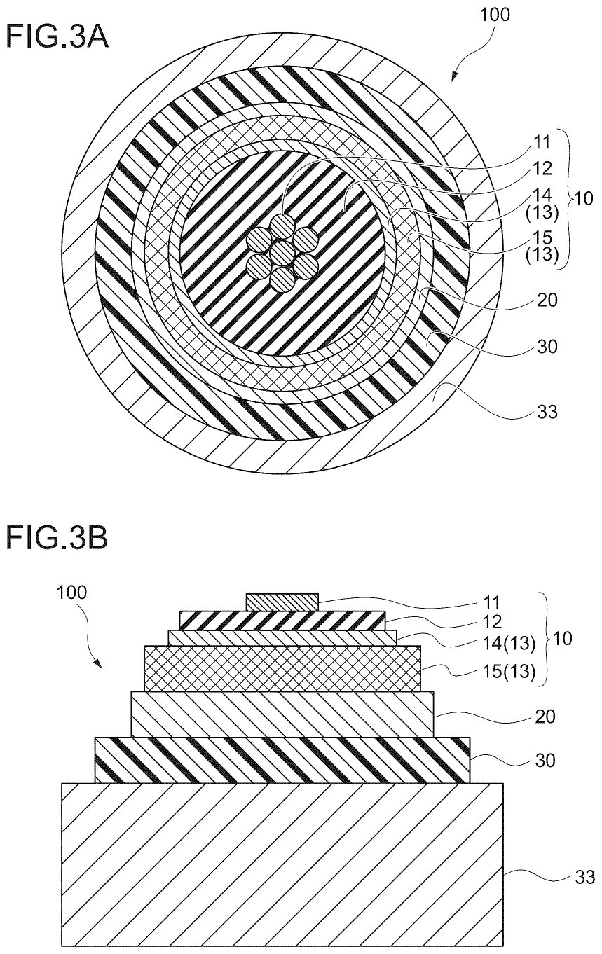

FIG. 3A is a schematic cross-sectional view showing a configuration example of the cable according to the present embodiment. FIG. 3B is a schematic side view showing the configuration example of the cable according to the present embodiment. FIG. 3A is a cross-sectional view of a cable 100 cut along a plane perpendicular to a center line that passes through a center of the cable 100, and FIG. 3B is a side view of the cable 100 as viewed from a direction perpendicular to the center line.

In the present embodiment, the cable 100 is configured as a coaxial cable. Hereinafter, an example in which the present technology is applied to the coaxial cable 100 will be described. It is noted that the present technology is not limited to the coaxial cable and can also be applied to other types of cables.

The cable 100 includes a transmission portion 10, a magnetic tape 20, a magnetic resin layer 30 (internal sheath), and an outer cover layer 33.

The transmission portion 10 is a portion of the cable 100 that has a basic structure for transmitting signals and power. The structure of the transmission portion 10 differs depending on the type of the cable 100. In the present embodiment, the transmission portion 10 has a structure as a coaxial cable. The transmission portion 10 includes a signal line 11, an insulation layer 12, and a shield layer 13.

The signal line 11 is a conductor that transmits signals and functions as an internal conductor (core wire) in the coaxial cable. For example, a twisted wire obtained by twisting soft copper wires is used as the signal line 11. It is noted that the material and structure of the signal line 11 are not limited.

The insulation layer 12 is a layer formed of an insulator that covers a circumference of the signal line 11, and prevents a short circuit between the signal line 11 and the shield layer 13 from occurring. As the insulation layer 12, for example, an insulator such as cross-linked polyethylene is provided. Alternatively, a resin such as foamed polyurethane may be used as the insulation layer 12.

In the present embodiment, the signal line 11 covered by the insulation layer 12 functions as a transmission line for transmitting signals. Herein, the transmission line is, for example, a wire rod capable of transmitting signals and power independently. For example, when there is a plurality of transmission lines, each of the transmission lines is configured as a wire rod that is insulated from one another.

The shield layer 13 is a conductor surrounding the transmission line (herein, a wire rod that includes the signal line 11 and the insulation layer 12) and functions as an electric field shield with respect to the signal line 11. In the present embodiment, the shield layer 13 is an external conductor in the coaxial cable and includes a conductor sheet 14 and a braided wire 15.

The conductor sheet 14 is a sheet-type conductor, typically a foil-type metal sheet. For example, a tape such as an aluminum foil with an adhesive on both sides is used as the conductor sheet 14. By using the conductor sheet 14, for example, it becomes possible to reflect electric field noise and improve shield performance of the shield layer 13.

Alternatively, a metal sheet formed of copper, iron, or the like may be used as the conductor sheet 14.

The braided wire 15 is formed by braiding a plurality of wires. For example, the braided wire 15 obtained by braiding soft copper wires having a wire diameter of about 0.1 mm, or the like is used. It is noted that the braided wire 15 may be plated with tin.

In the shield layer 13 shown in FIGS. 3A and 3B, the conductor sheet 14 (external conductor on inner side) is wound on an outer side of the insulation layer 12, and the braided wire 15 (external conductor on outer side) is further provided on the outer side of the conductor sheet 14. It is noted that the configuration of the shield layer 13 is not limited to this. For example, the conductor sheet 14 may be wound on the outer side of the braided wire 15. Alternatively, the shield layer 13 may be formed only by the braided wire 15 without providing the conductor sheet 14. Alternatively, a winding wire or the like obtained by winding a soft copper wire or the like may be used in place of the braided wire 15.

The braided wire 15 of the shield layer 13 is connected to a ground point of a circuit inside an electronic apparatus via a connector or the like, for example. The shield layer 13 is provided to suppress an intrusion of noise in the signal line 11 and to prevent noise from leaking outside from the signal line 11.

The magnetic tape 20 is a tape that includes a magnetic layer that absorbs radio waves and is wound around the transmission portion 10. By being provided with the magnetic layer, the magnetic tape 20 functions as a magnetic shield with respect to the transmission portion 10. In the present embodiment, the shield layer 13 is formed on an outermost side of the transmission portion 10. The magnetic tape 20 is wound around this shield layer 13 (specifically, braided wire 15). It is noted that although the structure of the magnetic tape 20 is omitted in FIGS. 3A and 3B, the magnetic tape 20 includes a plurality of layers including the magnetic layer as will be described below.

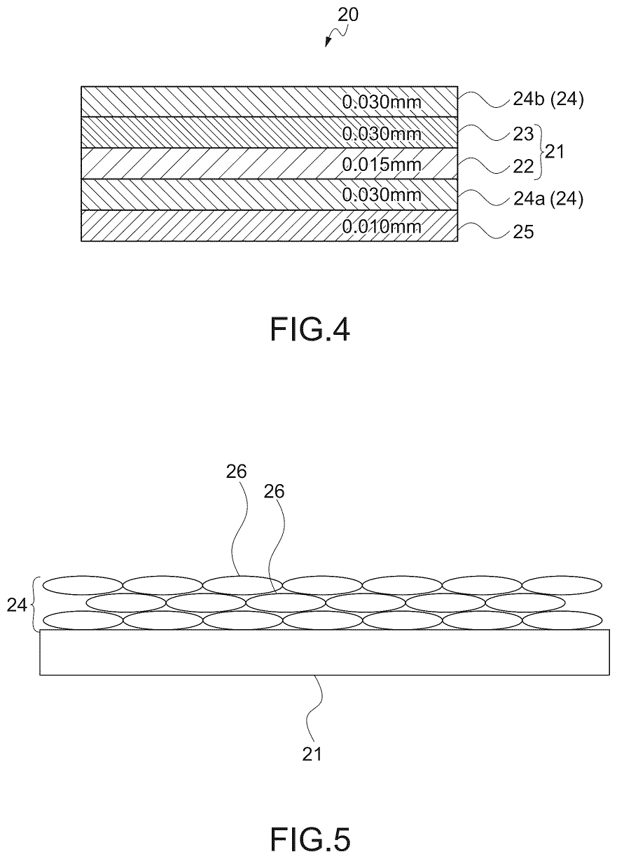

FIG. 4 is a schematic diagram showing a configuration example of the magnetic tape. FIG. 4 schematically shows a cross-sectional view of the magnetic tape 20 cut in a thickness direction. A lower side of the figure is a side of the magnetic tape 20 that faces the transmission portion 10. Hereinafter, the side of the magnetic tape 20 that faces the transmission portion 10 will be referred to as an inner side, and the opposite side will be referred to as an outer side.

The magnetic tape 20 includes a tape base material 21 (resin base material 22 and metal layer 23), a magnetic layer 24 (inner magnetic layer 24a and outer magnetic layer 24b), and an adhesive layer 25. As shown in FIG. 4, the magnetic tape 20 is provided with, in the stated order from the inner side, the adhesive layer 25, the inner magnetic layer 24a, the resin base material 22, the metal layer 23, and the outer magnetic layer 24b.

The tape base material 21 is a tape-like base material (core of magnetic tape 20) included in the magnetic tape 20. The magnetic layer 24 to be described later is formed on the tape base material 21. By using the tape base material 21, it becomes possible to easily realize, for example, a tape-like member (magnetic tape 20) including the magnetic layer 24 having a high shield effect.

In the present embodiment, the tape base material 21 is a resin tape formed of at least one of a polyester-based resin, a polyolefin-based resin, a cellulose derivative, a vinyl-based resin, or other polymer resins. The tape base material 21 includes the resin base material 22 which becomes a main body of the resin tape.

The resin base material 22 contains, for example, the polyester-based resin as a main component.

The polyester-based resin includes, for example, at least one type selected from the group consisting of PET (polyethylene terephthalate), PEN (polyethylene naphthalate), PBT (polybutylene terephthalate), PBN (polybutylene naphthalate), PCT (polycyclohexylene dimethylene terephthalate), PEB (polyethylene-p (oxybenzoate), and polyethylene bisphenoxycarboxylate). When the resin base material 22 contains two or more types of polyester-based resins, those two or more types of polyester-based resins may be mixed, copolymerized, or laminated. At least one of a terminal or a side chain of the polyester-based resin may be modified. The resin base material 22 may contain a resin other than the polyester-based resin to be described later in addition to the polyester-based resin.

In the present specification, the term “main component” refers to a component having a highest content ratio out of components included in the resin base material 22. For example, when the main component of the resin base material 22 is a polyester-based resin, the content ratio of the polyester-based resin in the resin base material 22 may be, for example, 50% by mass or more, 60% by mass or more, 70% by mass or more, 80% by mass or more, 90% by mass or more, 95% by mass or more, or 98% by mass or more with respect to a mass of the resin base material 22, or the resin base material 22 may be formed only of the polyester-based resin.

The resin base material 22 may contain a resin other than the polyester-based resin. In this case, the resin other than the polyester-based resin may be the main component of the constituent material of the resin base material 22. When the resin other than the polyester-based resin is the main component of the constituent material of the resin base material 22, a content ratio of the resin other than the polyester-based resin in the resin base material 22 may be, for example, 50% by mass or more, 60% by mass or more, 70% by mass or more, 80% by mass or more, 90% by mass or more, 95% by mass or more, or 98% by mass or more with respect to the mass of the resin base material 22, or the resin base material 22 may be formed only of the resin other than the polyester-based resin. The resin other than the polyester-based resin includes, for example, at least one type selected from the group consisting of a polyolefin-based resin, a cellulose derivative, a vinyl-based resin, and other polymer resins. When the resin base material 22 contains two or more types of these resins, those two or more types of materials may be mixed, copolymerized, or laminated.

The polyolefin-based resin includes, for example, at least one type selected from the group consisting of PE (polyethylene) and PP (polypropylene). The cellulose derivative includes, for example, at least one type selected from the group consisting of cellulose diacetate, cellulose triacetate, CAB (cellulose acetate butyrate), and CAP (cellulose acetate propionate). The vinyl-based resin includes, for example, at least one type selected from the group consisting of PVC (polyvinyl chloride) and PVDC (polyvinylidene chloride).

Other polymer resins include, for example, at least one type selected from the group consisting of PEEK (polyether ether ketone), PA (polyamide, nylon), aromatic PA (aromatic polyamide, aramid), PI (polyimide), aromatic PI (aromatic polyimide), PAI (polyamideimide), aromatic PAI (aromatic polyamideimide), PBO (polybenzoxazole, for example, Zylon®), polyether, PEK (polyetherketone), polyetherester, PES (polyethersulfone), PEI (polyetherimide), PSF (polysulfone), PPS (polyphenylene sulfide), PC (polycarbonate), PAR (polyarylate), and PU (polyurethane). Specifically, for example, the resin base material 22 may contain, as the main component, PEEK (polyether ether ketone), PA (polyamide, nylon), aromatic PA (aromatic polyamide, aramid), PI (polyimide), aromatic PI (aromatic polyimide), PAI (polyamideimide), aromatic PAI (aromatic polyamideimide), PBO (polybenzoxazole, for example, Zylon®), polyether, PEK (polyetherketone), polyetherester, PES (polyethersulfone), PEI (polyetherimide), PSF (polysulfone), PPS (polyphenylene sulfide), PC (polycarbonate), PAR (polyarylate), or PU (polyurethane).

Furthermore, the tape base material 21 may include the metal layer 23. The metal layer 23 is formed on a surface of the resin base material 22 and is formed of, for example, one of aluminum, copper, and iron. A metal foil formed of these metals is used as the metal layer 23. In this case, the tape base material 21 is formed by attaching the metal foil (metal layer 23) to the resin base material 22.

In this manner, in the present embodiment, the tape base material 21 is a resin tape in which the metal layer 23 is formed. The tape base material 21 including the metal layer 23 functions as an electric field shield. This makes it possible to suppress an influence of an electric field component (electric field noise) of spatial noise propagating in a space outside the cable 100, and the like, for example. It is noted that the metal layer 23 does not need to be grounded.

The magnetic layer 24 is a layer formed of a magnetic material that absorbs radio waves, and is formed on the surface of the tape base material 21. The magnetic layer 24 functions as a magnetic shield. As the magnetic material that forms the magnetic layer 24, for example, iron powder, ferrite powder, carbon powder, or the like is used. These powdered magnetic materials (hereinafter, will be referred to as magnetic powder) are used alone or in combination. The type of magnetic powder is not limited, and Ni—Cu—Zn-based ferrite magnetic powder, Mn—Zn-based ferrite magnetic powder, soft magnetic metal-based magnetic powder, copper-based magnetic powder, magnesium-based magnetic powder, lithium-based magnetic powder, zinc-based magnetic powder, iron-based (e.g., permalloy) magnetic powder, cobalt-based magnetic powder, and/or the like can be used.

FIG. 5 is a schematic diagram showing a configuration example of the magnetic layer. In FIG. 5, a layer of magnetic powder 26 formed on the surface of the tape base material 21 is illustrated as an example of the magnetic layer 24.

In the present embodiment, the magnetic layer 24 is a coating layer of the magnetic powder 26 (magnetic material) that has been applied such that the magnetic powder 26 is oriented on the surface of the tape base material 21.

A state where the magnetic powder 26 (magnetic material) is oriented is, for example, a state where orientations of the magnetic powder 26 having similar shapes are mechanically aligned. The magnetic powder 26 is, for example, powder having a flat shape. In FIG. 5, the flat-shaped magnetic powder 26 is schematically illustrated as elliptical powder. In this case, a state where each magnetic powder 26 is stacked along the surface of the tape base material 21 (a state where a longitudinal direction of an ellipse is provided along the surface of the tape base material 21 in FIG. 5) is the state where the magnetic powder 26 is oriented. Further, for example, in a case where the magnetic powder 26 is needle-like powder, a state where the longitudinal direction of each magnetic powder 26 is aligned becomes the state where the magnetic powder 26 is oriented.

For example, a blade is arranged above the tape base material 21 onto which a slurry containing the magnetic powder 26 has been applied, the blade used for uniformizing a thickness of the slurry while a certain interval is provided between the tape base material 21 and the blade. By relatively moving the blade with respect to the tape base material 21, the magnetic powder 26 in the slurry can be mechanically oriented along the surface of the tape base material 21. As a result, the coating layer in which the magnetic powder 26 is oriented is formed on the surface of the tape base material 21. In addition, the method of applying the magnetic powder 26 is not limited, and other methods may be used. For example, the magnetic powder 26 may be oriented by applying an external magnetic field to the tape base material 21 onto which the slurry containing the magnetic powder 26 has been applied.

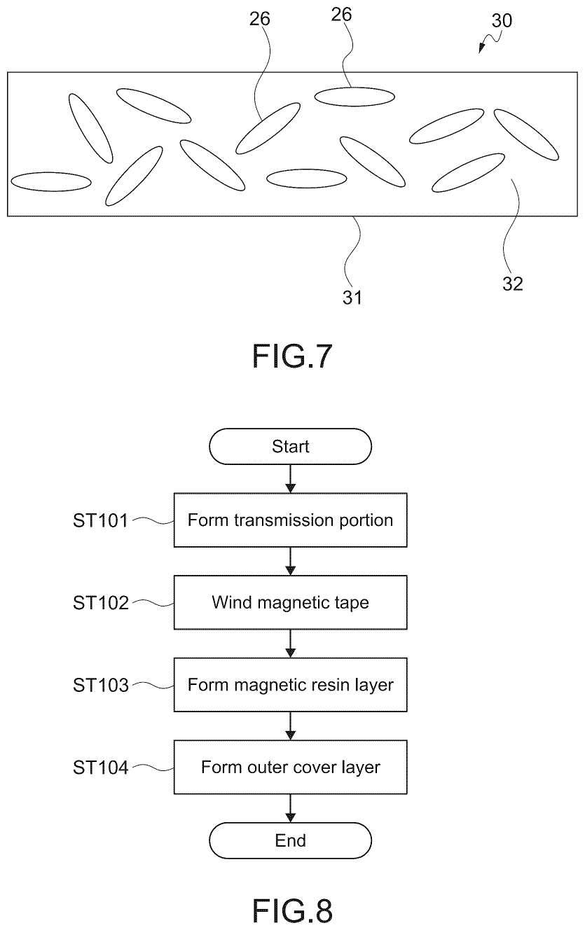

In this manner, the magnetic powder 26 is arranged on the surface of the tape base material 21 in the state where the magnetic powder 26 is oriented. Accordingly, for example, compared to a magnetic resin in which the magnetic powder 26 is dispersed in the resin (see FIG. 7) or the like, magnetic permeability of the entire magnetic layer 24 becomes sufficiently high, and thus it becomes possible to significantly improve the magnetic shield effect.

It is noted that methods other than the application may be used as the method of forming the magnetic layer 24. For example, the magnetic layer 24 may be formed by depositing the magnetic powder 26 onto the tape base material 21. In this case, the magnetic layer is a deposited film of the magnetic powder 26 (magnetic material) that is formed on the surface of the tape base material 21. Alternatively, for example, the magnetic layer 24 may be formed by sputtering using a sputtering source containing the magnetic powder. In this case, the magnetic layer is a sputtered film of the magnetic powder 26 (magnetic material).

When using vapor deposition or sputtering, the magnetic powder 26 is oriented during a process of being laminated on the tape base material 21. By using these methods, it becomes possible to form, for example, a precise laminated film having a desired film thickness as the magnetic layer 24.

Returning to FIG. 4, in the present embodiment, the magnetic layer 24 is formed on both sides of the tape base material 21. The magnetic layer 24 formed on the inner side of the tape base material 21 is the inner magnetic layer 24a, and the magnetic layer 24 formed on the outer side of the tape base material 21 is the outer magnetic layer 24b. That is, the inner magnetic layer 24a is formed on the inner side of the resin base material 22, and the outer magnetic layer 24b is formed on the outer side of the metal layer 23. At least one of the inner magnetic layer 24a or the outer magnetic layer 24b is configured such that the magnetic material is oriented.

The inner magnetic layer 24a functions as a magnetic shield with respect to conductive noise that propagates through the transmission portion 10, and attenuates the conductive noise, for example. Further, the outer magnetic layer 24b functions as a magnetic shield with respect to spatial noise that propagates through the space outside the cable 100, and suppresses the intrusion of spatial noise into the transmission portion 10, for example.

In general, complex magnetic permeability μ is expressed by a real part μ′ of an inductance component and an imaginary part μ″ corresponding to a resistance component (loss component) as shown in the following equation (1), where j is an imaginary unit.

$$μ = {μ}^{′} - j {μ}^{″} \qquad ( 1 )$$

Comparing the inner magnetic layer 24a and the outer magnetic layer 24b, the inner magnetic layer 24a has a function of converting conductive noise into heat by a high frequency resistance indicated by the imaginary part μ″, and the outer magnetic layer 24b has a function as the magnetic shield to prevent an influence of the magnetic field by the inductance component indicated by the real part μ′. In other words, the inner magnetic layer 24a blocks the conductive noise that is carried on an outer coating of the braided wire 15 of the shield layer 13 by the high frequency impedance of the magnetic material (ferrite and/or the like). Moreover, the outer magnetic layer 24b forms a magnetic shield so as to prevent the influence of spatial noise from outside.

Furthermore, the effect of the magnetic material (ferrite and/or the like) in the inner magnetic layer 24a depends on a volume of the magnetic material. Regarding this point, since the inner magnetic layer 24a is formed across the same distance as the length of the cable 100, it is possible to increase the volume of the magnetic material. Therefore, even without increasing the thickness of the inner magnetic layer 24a, the high frequency impedance of the cable 100 becomes high, and the conductive noise carried on the outer coating of the braided wire 15 of the shield layer 13 can be sufficiently suppressed.

The adhesive layer 25 is formed on the innermost side of the magnetic tape 20, that is, on the side of the magnetic tape 20 that faces the transmission portion 10. The adhesive layer 25 is provided so as to cause the magnetic tape 20 to adhere onto the transmission portion 10, and is formed by using an adhesive or the like. A specific configuration of the adhesive layer 25 is not limited, but it is favorable for the thickness of the adhesive layer 25 to be small in order to reduce a gap or the like that is formed between the magnetic tape 20 on the inner side and the magnetic tape 20 on the outer side when the magnetic tape 20 is wound, for example.

The magnetic tape 20 shown in FIG. 4 is, for example, a tape having a width of 7 mm. Further, of the tape base material 21 which is the core of the magnetic tape 20, the resin base material 22 is a PET tape having a thickness of 0.015 mm, and the metal layer 23 is an aluminum foil sheet having a thickness of 0.03 mm. In addition, the inner magnetic layer 24a and the outer magnetic layer 24b provided on the inner side and outer side of the tape base material 21 both have a thickness of 0.03 mm, and are formed by being applied such that the magnetic material is oriented. Moreover, the adhesive layer 25 formed on the inner side of the inner magnetic layer 24a has a thickness of 0.01 mm. It is noted that these sizes and materials are mere examples, and the width of the magnetic tape 20 and the thicknesses of the respective layers can be set arbitrarily. Further, the materials of the respective layers may be selected as appropriate from the materials described above, for example. Furthermore, it is not always necessary to provide the adhesive layer 25, and the magnetic tape 20 not provided with the adhesive layer 25 may be formed.

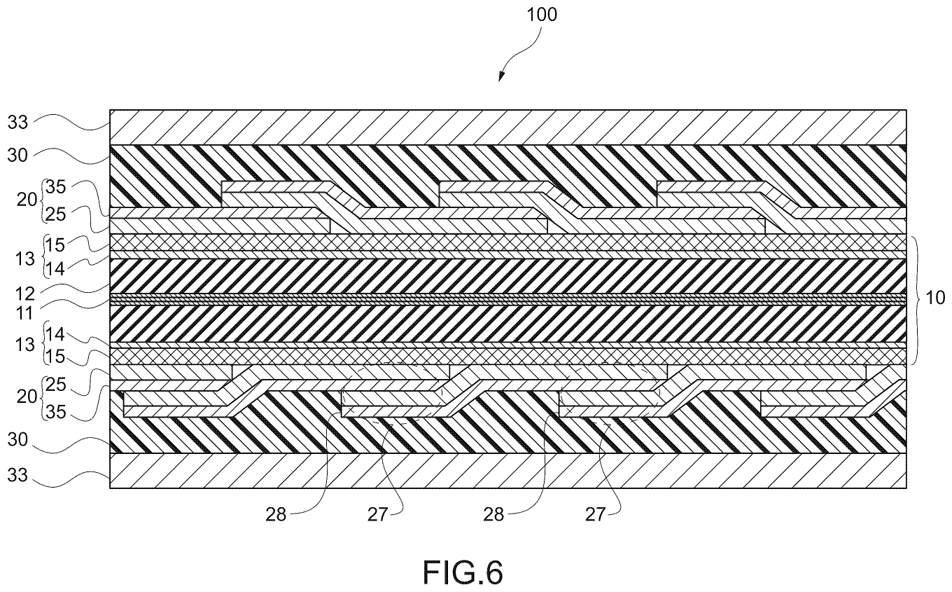

FIG. 6 is a schematic cross-sectional view showing a configuration example of the cable shown in FIGS. 3A and 3B. FIG. 6 schematically shows a cross-sectional view of the cable 100 cut along a plane including the center line of the cable 100. It is noted that in FIG. 6, the layers other than the adhesive layer 25, that are included in the magnetic tape 20, are omitted. Herein, the layers other than the adhesive layer 25 may be referred to as a tape body 35.

As shown in FIG. 6, the magnetic tape 20 is wound transversely around the transmission portion 10. The transverse winding is a method of spirally winding the tape while the tape is closely attached to a surface of a target. Accordingly, by winding the magnetic tape 20, it is possible to avoid a

In situation where flexibility of the cable 100 is lowered. addition, a stress applied to the magnetic tape 20 when the cable 100 is bent or the like is reduced. As a result, the magnetic tape 20 is less likely to be deformed at the bent portion, and a gap that is due to the bending, or the like is less likely to be caused between the magnetic tape 20 and the transmission portion 10 or between portions of the wound magnetic tape 20.

In the present embodiment, the magnetic tape 20 is wound transversely around the transmission portion 10 such that parts of the magnetic tape 20 overlap in a width direction. In other words, as shown in FIG. 6, the magnetic tape 20 is spirally wound such that a part of the magnetic tape 20 overlaps an already-wound part from above. By causing parts of the magnetic tape 20 to overlap in this manner, it becomes possible to effectively suppress the intrusion of the magnetic field noise and the like. Moreover, a situation where the transmission portion 10 becomes exposed when the cable 100 is bent is avoided, and deterioration of the shield performance can be suppressed.

The magnetic resin layer 30 is formed of a magnetic resin that absorbs radio waves, and covers the magnetic tape 20. Since the magnetic resin layer 30 is formed of a magnetic resin, the magnetic resin layer 30 itself has a function as a magnetic shield.

It is favorable for the magnetic resin layer 30 to directly cover the magnetic tape 20. Herein, directly covering the magnetic tape 20 means providing the magnetic resin layer 30 such that the outer surface of the magnetic tape 20 and the magnetic resin come into contact with each other.

In the present embodiment, the outer magnetic layer 24b is formed on the outermost side of the magnetic tape 20. The magnetic resin layer 30 directly covers this outer magnetic layer 24b. In other words, the magnetic resin layer 30 is formed to cover the circumference of the magnetic tape 20 (outer magnetic layer 24b) in a state of being in contact with the outer surface of the magnetic tape 20 (outer magnetic layer 24b).

FIG. 7 is a schematic diagram showing a configuration example of the magnetic resin. FIG. 7 schematically shows a cross-sectional configuration of a magnetic resin 31 used in the magnetic resin layer 30. The magnetic resin 31 includes a synthetic resin 32 that is a base material, and the magnetic powder 26 (magnetic material), and the magnetic resin 31 is a magnetic powder mixed resin in which the synthetic resin 32 is mixed with the magnetic powder 26.

An example of the synthetic resin 32 is polyvinyl chloride (PVC). Other than this, synthetic resins such as styrene-based elastomer and olefin-based elastomer may also be used.

As the magnetic powder 26 (magnetic material), for example, iron powder, ferrite powder, carbon powder, and/or the like are used. These magnetic powders 26 are mixed alone or in combination into the synthetic resin 32. The type of magnetic powder is not limited, and Ni—Cu—Zn-based ferrite magnetic powder, Mn—Zn-based ferrite magnetic powder, soft magnetic metal-based magnetic powder, copper-based magnetic powder, magnesium-based magnetic powder, lithium-based magnetic powder, zinc-based magnetic powder, iron-based (for example, permalloy) magnetic powder, cobalt-based magnetic powder, and/or the like can be used, for example.

It is noted that the type of magnetic powder 26 contained in the magnetic resin layer 30 and the type of magnetic powder 26 included in the magnetic layer 24 of the magnetic tape 20 described above may be the same or may be different.

Moreover, a ratio of iron powder or ferrite powder contained in the magnetic resin 31 is 70% or more and 90% or less by weight in the magnetic resin 31. By forming the magnetic resin 31 in this manner, it becomes possible to exert effective shield performance while maintaining flexible deformation characteristics as a resin.

As shown in FIG. 7, the orientation of the magnetic powder 26 is not uniform inside the magnetic resin 31, and the magnetic powder 26 is dispersed in a state in which particles are facing various directions. In other words, unlike the magnetic layer 24 of the magnetic tape 20 that has been described with reference to FIG. 5, the magnetic powder 26 is not oriented inside the magnetic resin 31.

In this manner, even when the magnetic powder 26 is not oriented, the magnetic resin 31 functions as the magnetic shield. Furthermore, the outer side of the magnetic tape 20 can be coated with the magnetic resin 31 without any gap. This makes it possible to reinforce, for example, a portion of the magnetic tape 20 where the shield effect becomes weak (a gap of the magnetic tape 20, and/or the like) by the magnetic resin 31. This point will be described later.

As shown in FIGS. 3A, 3B, and 6, the cable 100 is provided with the insulating outer cover layer 33 that covers a circumference of the magnetic resin layer 30. The outer cover layer 33 is also referred to as a sheath in general, and is a cover that protects the inside of the cable 100 and prevents electric leakage from the cable 100 or the like from occurring.

The outer cover layer 33 is formed of, for example, an insulating material such as polyethylene, polypropylene, PVC, and elastomer.

[Operation of cable]

The magnetic layer 24 included in the magnetic tape 20 is a layer formed on the tape base material 21 by application, vapor deposition, or the like in a state in which the orientation of the magnetic material (magnetic powder 26) is aligned (see FIG. 5). Therefore, the magnetic permeability of the magnetic tape 20 becomes extremely higher than that of the magnetic resin 31 (see FIG. 7) in which the magnetic material (magnetic powder 26) is dispersed in the synthetic resin 32, for example.

As an example, it was found that the real part μ′ of the complex magnetic permeability was 8 in the magnetic resin 31 but became 200 in the magnetic layer 24 of the magnetic tape 20, and the imaginary part μ″ of the complex magnetic permeability was 2 in the magnetic resin 31 but became 50 in the magnetic layer 24 of the magnetic tape 20. In this manner, in the magnetic layer 24 in which the magnetic material is oriented, both the real part and the imaginary part of the complex magnetic permeability are improved, and thus it becomes possible to significantly improve the performance as the magnetic shield.

Since the magnetic tape 20 is a tape-like member, the magnetic tape 20 is used by being wound around the transmission portion 10 of the cable 100. In addition, as shown in FIG. 6, considering the flexibility of the cable 100 and the like, the magnetic tape 20 is wound transversely around the transmission portion 10 in the present embodiment. At this time, the magnetic tape 20 is wound such that parts of the magnetic tape 20 overlap in the width direction and such that the transmission portion 10 is not exposed.

In this manner, the magnetic tape 20 is provided so as to avoid discontinuities in the magnetic material as much as possible, but the magnetic tape 20 may be arranged via the adhesive layer 25 (adhesive or the like), which causes a gap between the tapes. For example, in FIG. 6, focusing on an overlapping portion (hereinafter, will be referred to as an overlapping portion 27) of the magnetic tape 20, the tape body 35 on the outer side overlaps the tape body 35 on the inner side via the adhesive layer 25. In other words, a gap is formed by the adhesive layer 25 between the overlapping tape bodies 35. This gap becomes a discontinuity in the magnetic layer 24 (the inner magnetic layer 24a and the outer magnetic layer 24b) included in the tape body 35, which may lead to lowering of the shield performance.

Particularly when the cable 100 is bent, the gap or the like at the overlapping portion 27 becomes large, and thus the shield performance of the magnetic tape 20 may largely deteriorate.

In this regard, in the cable 100, in order to compensate for such lowering of the shield performance, the outside of the magnetic tape 20 is covered by the magnetic resin 31 (magnetic resin layer 30). Accordingly, the magnetic tape 20 including a portion where a gap is generated in the magnetic tape 20 (specifically, a side end surface 28 of the magnetic tape 20 on the outer side at the overlapping portion 27) is entirely covered by the magnetic resin 31. As a result, for example, it becomes possible to connect, by the magnetic resin 31, the outer surface (outer magnetic layer 24b) of the magnetic tape 20 on the inner side at the overlapping portion 27 and the outer surface (outer magnetic layer 24b) of the magnetic tape 20 on the outer side at the overlapping portion 27.

The magnetic resin 31 is a material that allows a magnetic flux to pass inside in spite of lower magnetic permeability than the magnetic tape 20. Therefore, by covering with the magnetic resin 31, the magnetic flux is not cut off at a portion corresponding to the gap of the magnetic tape 20. In other words, the magnetic resin 31 exerts a function of connecting the magnetic fluxes at the gaps formed between the magnetic tapes 20. As a result, the performance of the cable 100 as the magnetic shield is significantly improved.

In particular, since the magnetic tape 20 is provided with the magnetic layer 24 on the outer side (outer magnetic layer 24b), the magnetic layer 24 covered by the magnetic resin 31 functions as a magnetic material that is continuous throughout the cable 100, and exerts high shield performance. From such a viewpoint, it is favorable for the magnetic layer to be formed on at least the side of the tape base material 21 that faces the outer side.

In this manner, in the cable 100, a tape-like member (magnetic tape 20) is wound on the outer side of the transmission portion 10 for transmitting signals and the like in a state in which the orientation of the magnetic material is aligned, and the outer side of the tape is further covered by the resin containing the magnetic material (magnetic resin 31). Accordingly, a situation where the magnetic flux is cut off at the gaps of the magnetic tape 20 is avoided, and it becomes possible to prominently improve the shield performance of the cable 100.

### [Cable Manufacturing Method]

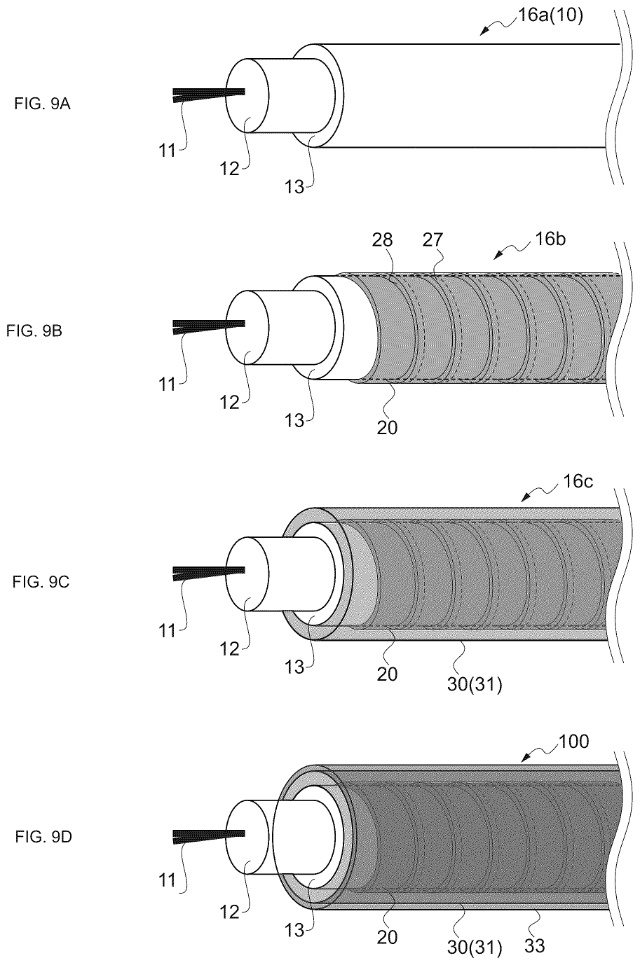

FIG. 8 is a flowchart showing an example of a cable manufacturing method. FIG. 9 is a schematic diagram for explaining steps for manufacturing a cable. Hereinafter, the manufacturing method of the cable 100 will be described with reference to FIGS. 8 and 9.

First, the transmission portion 10 including the signal line 11 for transmitting signals is formed (Step 101). A of FIG. 9 schematically shows the transmission portion 10 formed in Step 101. Hereinafter, the transmission portion 10 may be referred to as an intermediate wire rod 16a.

In the step of forming the transmission portion 10, first, a twisted wire obtained by twisting soft copper wires together is formed as the signal line 11, for example. After the signal line 11 is formed, the insulation layer 12 that covers the circumference of the signal line 11 is formed. The insulation layer 12 is typically formed by extrusion molding.

Extrusion molding is a method of continuously molding a resin by extruding heated and molten resin from a mold (die). For example, the signal line 11 is passed through the mold so that, while the signal line 11 is pulled out, the heated and molten resin that is to become the insulation layer 12 is extruded onto the circumference of the signal line 11. Accordingly, the circumference of the signal line 11 is covered by the molten resin. The resin that has covered the signal line 11 is cooled by being passed through a water channel or the like. As a result, the insulation layer 12 is formed around the signal line 11.

After the insulation layer 12 is formed, the shield layer 13 is formed around the insulation layer 12. In the present embodiment, the conductor sheet 14 and the braided wire 15 are provided as the shield layer 13. It is noted that in A of FIG. 9, the shield layer 13 is illustrated in a state in which illustrations of the conductor sheet 14 and the braided wire 15 are omitted.

The conductor sheet 14 is, for example, a tape-like member provided with an adhesive, and is wound transversely on the insulation layer 12 in a state in which the adhesive is adhered onto the outer side of the insulation layer 12.

It is noted that the conductor sheet 14 may be wound longitudinally. Longitudinal winding is, for example, a method of winding a sheet in a state of closely being attached to a surface of the wire rod, such that an extension direction of the sheet coincides with an extension direction of a wire rod on which the sheet is to be wound. In this case, the conductor sheet 14 is wound longitudinally around the insulation layer 12 such that end portions of the conductor sheet 14 provided along the extension direction overlap.

After the conductor sheet 14 is wound, the braided wire 15 is formed on the outer side of the conductor sheet 14. For example, a plurality of soft copper wires (element wires) is woven on the outer side of the conductor sheet 14 to form the braided wire 15. It is noted that as the shield layer 13, the braided wire 15 may be formed first, and then the conductor sheet 14 may be wound on the outer side of the braided wire 15. Alternatively, the shield layer 13 may only include the braided wire 15.

After the intermediate wire rod 16a that is to become the transmission portion 10 is formed, the magnetic tape 20 including the magnetic layer 24 that absorbs radio waves is wound around the transmission portion 10 (Step 102). B of FIG. 9 schematically shows the magnetic tape 20 wound in Step 102. Herein, an illustration of the structure of the magnetic layer 24 and the like included in the magnetic tape 20 is omitted. Hereinafter, a wire rod in which the magnetic tape 20 is wound on the outer side of the intermediate wire rod 16a that is the transmission portion 10 may be referred to as an intermediate wire rod 16b.

As shown in B of FIG. 9, the intermediate wire rod 16b is formed by transversely winding the magnetic tape 20 on the outer side of the intermediate wire rod 16a (the outer side of the shield layer 13 of the transmission portion 10) such that parts of the magnetic tape 20 partially overlap. For example, a feeder that supplies the magnetic tape 20 supplies the magnetic tape 20 while rotating around the intermediate wire rod 16a that is fed out at a constant speed, so that the magnetic tape 20 is wound transversely in a spiral around the intermediate wire rod 16a. At this time, the speed at which the intermediate wire rod 16a is fed out and the rotation speed of the feeder are set as appropriate so that parts of the magnetic tape 20 partially overlap.

In this manner, the magnetic tape 20 is spirally wound such that the end portions of the magnetic tape 20 provided along the extension direction overlap. Therefore, the overlapping portion 27 where parts of the magnetic tape 20 overlap and the side end surface 28 of the magnetic tape 20 on the outer side at the overlapping portion 27 are also formed in a spiral. It is noted that in FIG. 9B, an end side of the magnetic tape 20 on the inner side at the overlapping portion 27 is indicated by a dotted line.

Herein, the magnetic tape 20 that has been manufactured in advance is prepared to manufacture the cable 100, but a step of manufacturing the magnetic tape 20 may be carried out before Step 102.

In the step of manufacturing the magnetic tape 20, first, the resin base material 22 (tape base material 21) having the metal layer 23 provided on the surface thereof is formed. For example, an aluminum foil that is to become the metal layer 23 is attached to the resin base material 22.

Next, the magnetic layer 24 is formed on the surface of the tape base material 21 such that the magnetic material is oriented. In the present embodiment, the inner magnetic layer 24a is formed on the inner side of the tape base material 21, and the outer magnetic layer 24b is formed on the outer side of the tape base material 21. The inner magnetic layer 24a and the outer magnetic layer 24b are formed by, for example, applying a slurry containing the magnetic material. Alternatively, the inner magnetic layer 24a and the outer magnetic layer 24b may be formed by, for example, vapor deposition or sputtering.

After the magnetic layer 24 is formed, the adhesive layer 25 is formed on the surface on the inner side of the magnetic tape 20 (the surface of the inner magnetic layer 24a). For example, the adhesive layer 25 is formed by applying an adhesive to the surface on the inner side of the magnetic tape 20.

The magnetic tape 20 manufactured in this manner is wound around the intermediate wire rod 16a from the predetermined feeder to thus form the intermediate wire rod 16b.

After the intermediate wire rod 16b having the magnetic tape 20 wound thereon is formed, the magnetic tape 20 is covered by the magnetic resin 31 that absorbs radio waves to thus form the magnetic resin layer 30 (Step 103). C of FIG. 9 schematically shows the magnetic resin layer 30 formed in Step 103. Hereinafter, a wire rod in which the outer side of the intermediate wire rod 16b obtained by winding the magnetic tape 20 around the transmission portion 10 is covered by the magnetic resin layer 30 may be referred to as an intermediate wire rod 16c.

Extrusion molding is typically used to form the magnetic resin layer 30. For example, the intermediate wire rod 16b is passed through a mold so that, while the intermediate wire rod 16b is pulled out, the heated and molten magnetic resin 31 is extruded onto the circumference of the intermediate wire rod 16b (magnetic tape 20). Accordingly, the circumference of the magnetic tape 20 is covered by the molten resin. The magnetic resin 31 that has covered the magnetic tape 20 is cooled by being passed through a water channel or the like. As a result, the magnetic resin layer 30 is formed around the magnetic tape 20.

In this manner, the magnetic resin layer 30 is a resin coating formed by extruding the magnetic resin 31 onto the intermediate wire rod 16b having the magnetic tape 20 wound around the transmission portion 10. Herein, the intermediate wire rod 16b corresponds to an intermediate body having a magnetic tape wound around a transmission portion.

As described above, in the extrusion molding, the molten magnetic resin 31 is supplied to the circumference of the magnetic tape 20. Therefore, the magnetic tape 20 including the side end surfaces 28 that become discontinuities in the magnetic layer 24 at the overlapping portions 27 is entirely covered by the magnetic resin 31 without any gaps. This makes it possible to sufficiently avoid a situation where the magnetic flux is cut off at the gap between the magnetic tapes 20 and the like to cause noise to enter the transmission portion 10.

After the intermediate wire rod 16c covered by the magnetic resin layer 30 is formed, the outer cover layer 33 is formed around the magnetic resin layer 30 (Step 104). D of FIG. 9 schematically shows the outer cover layer 33 formed in Step 104. The intermediate wire rod 16c provided with the outer cover layer 33 becomes the cable 100.

Extrusion molding is typically used to form the outer cover layer 33. For example, the intermediate wire rod 16c is passed through a mold so that, while the intermediate wire rod 16c is pulled out, a heated and molten insulating resin (a resin that is to become the outer cover layer 33) is extruded onto the circumference of the intermediate wire rod 16c (magnetic resin layer 30). Accordingly, the circumference of the magnetic resin layer 30 is covered by the molten resin. The magnetic resin 31 that has covered the magnetic resin layer 30 is cooled by being passed through a water channel or the like. As a result, the outer cover layer 33 is formed around the magnetic resin layer 30.

### [Evaluation of Noise Characteristics]

Hereinafter, an evaluation of noise characteristics of the cable 100 according to the present embodiment that has been described with reference to FIGS. 3A and 3B and the like will be described. As the evaluation of noise characteristics, an emission measurement (radiation noise evaluation) which measures spatial noise radiated from the cable 100 and an immunity measurement (noise resistance evaluation) which measures spatial noise entering the cable 100 were carried out. Further, in each of the measurements, two types of comparison cables were used for comparison.

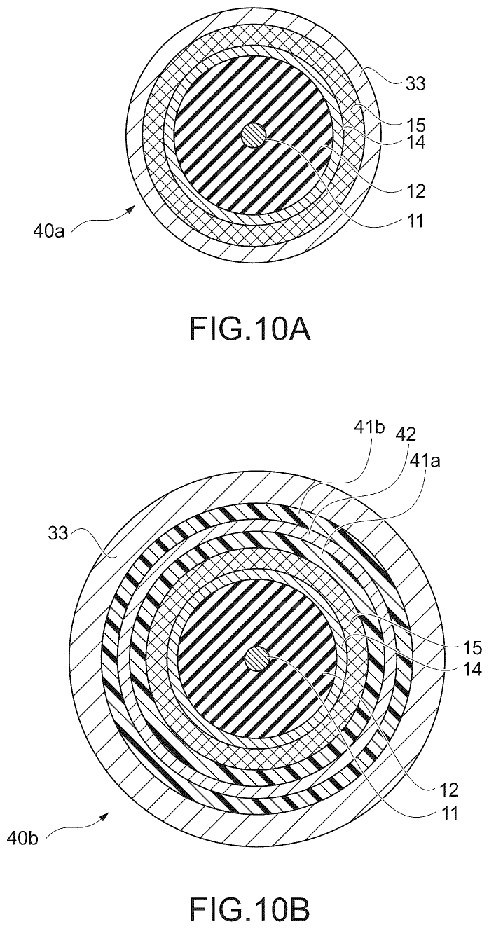

FIGS. 10A and 10B are schematic diagrams for explaining configurations of the comparison cables.

The comparison cable 40a shown in FIG. 10A is a normal coaxial cable not provided with a magnetic shield. In the comparison cable 40a, the signal line 11, the insulation layer 12, the conductor sheet 14, the braided wire 15, and the outer cover layer 33 are provided in the stated order from the inner side. That is, in the comparison cable 40a, a layer that uses the magnetic material (a layer to become the magnetic shield) is not provided around the transmission portion (the signal line 11, the insulation layer 12, the conductor sheet 14, and the braided wire 15).

The comparison cable 40b shown in FIG. 10B is a coaxial cable in which a layer formed of a magnetic resin is provided doubly as the magnetic shield (double ferrite coaxial cable). In the comparison cable 40b, the signal line 11, the insulation layer 12, the conductor sheet 14, the braided wire 15, an inner magnetic resin layer 41a, an outer shield layer 42, an outer magnetic resin layer 41b, and the outer cover layer 33 are provided in the stated order from the inner side. Of these, the signal line 11, the insulation layer 12, the conductor sheet 14, and the braided wire 15 form the transmission portion. In addition, the two magnetic resin layers 41a and 41b provided such that the outer shield layer 42 is situated between the two magnetic resin layers 41a and 41b function as the magnetic shield.

The emission measurement and the immunity measurement were performed in an anechoic chamber for three types of cables: the comparison cable 40a, the comparison cable 40b, and the cable 100 described in the present embodiment. The length of each cable used in the measurements was 1.7 m. Further, the measurements were performed while switching an antenna depending on a measurement frequency. Specifically, a biconical antenna was used for the measurements from 30 MHz to 300 MHz, and a log periodic antenna was used for the measurements from 300 MHz to 1 GHZ.

Furthermore, each measurement was performed while switching a direction of the antenna between the horizontal direction and the vertical direction. By looking at the measurement results in both cases where the antenna is arranged in the horizontal direction and the vertical direction, it is possible to properly evaluate an intensity of the spatial noise radiated from the antenna and the spatial noise entering the antenna.

### [Emission Measurement]

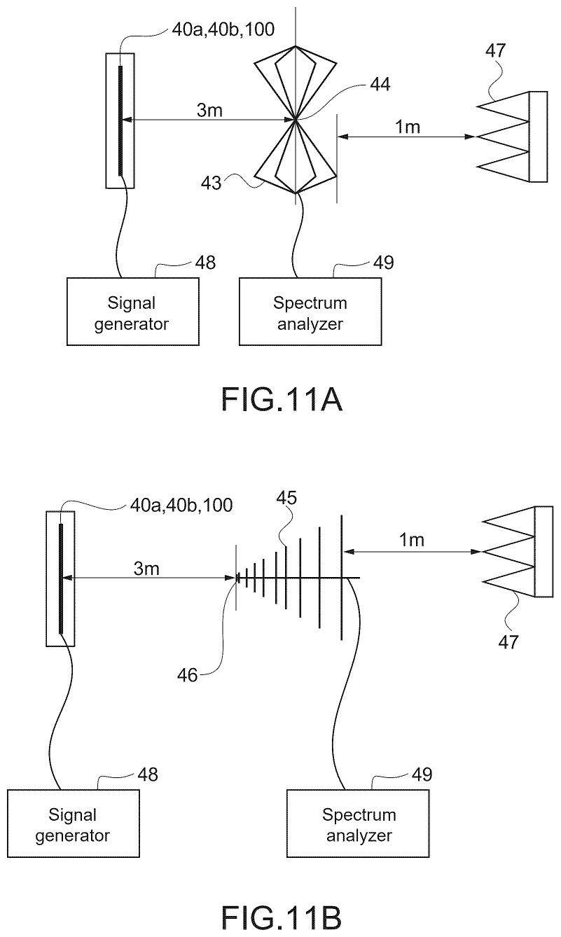

FIGS. 11A and 11B are schematic diagrams each showing an example of the emission measurement. FIG. 11A is a diagram showing an example of arrangement of the emission measurement that uses a biconical antenna 43, and FIG. 11B is a diagram showing an example of arrangement of the emission measurement that uses a log periodic antenna 45.

The measurement cables (the comparison cable 40a, the comparison cable 40b, and the cable 100) to be measured were arranged horizontally. Further, the biconical antenna 43 and the log periodic antenna 45 were arranged such that a minimum distance with respect to a radio wave absorbing member 47 provided on a wall surface of the anechoic chamber becomes 1 m, and a distance with respect to the measurement cables becomes 3 m. For example, in the case of the biconical antenna 43, a distance between a center position 44 and the measurement cables was set to 3 m. Meanwhile, in the case of the log periodic antenna 45, a distance between a tip end portion 46 on a side where a shortest antenna element is arranged and the measurement cables was set to 3 m.

One end of the measurement cable was connected to a signal generator 48 that outputs a measurement signal, and the other end of the measurement cable was terminated at 50Ω, which is the impedance of the coaxial line. In addition, the biconical antenna 43 and the log periodic antenna 45 were connected to a spectrum analyzer 49 that detects frequency components.

In the emission measurement, a signal of 10 dBm was output from the signal generator 48 while sweeping the frequency, and this signal was applied to the measurement cable terminated at 50Ω. At this time, the power level radiated from the measurement cable was measured using the biconical antenna 43 and the log periodic antenna 45. Hereinafter, the power level radiated from the measurement cable may be referred to as the radiation intensity of the measurement cable.

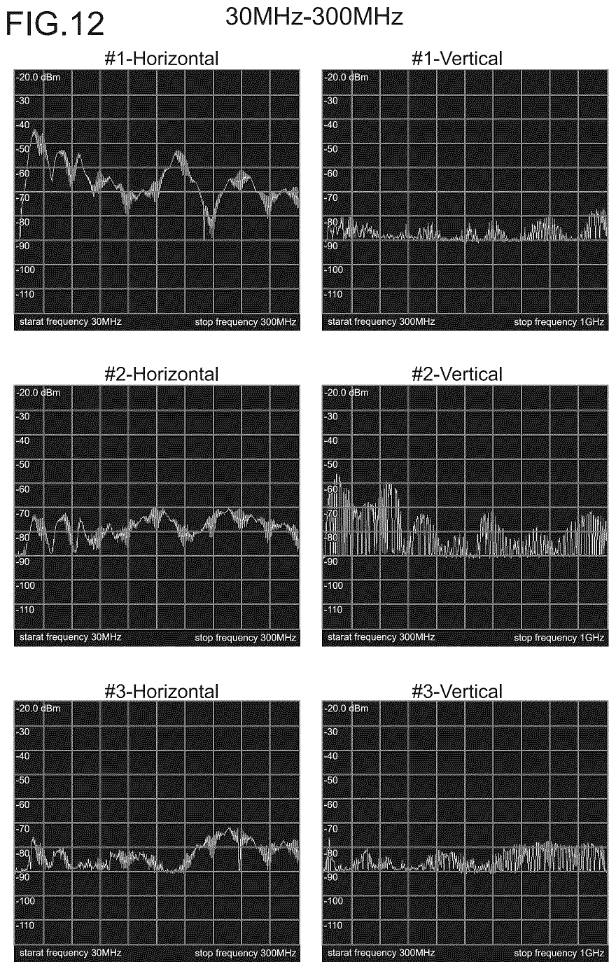

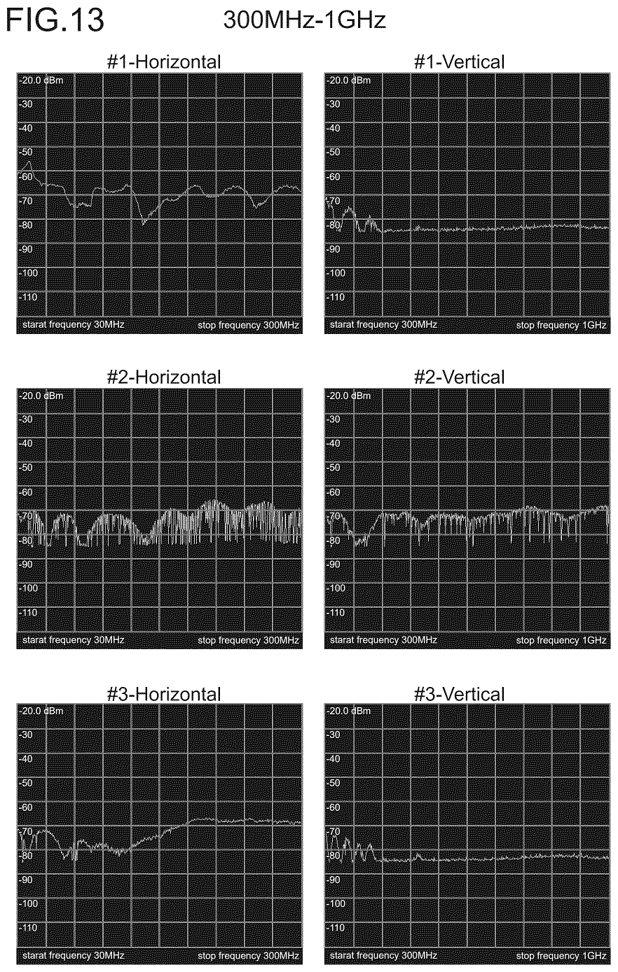

FIGS. 12 and 13 are graphs showing the measurement results of the emission measurement. FIG. 12 shows the results of the emission measurement from 30 MHz to 300 MHz, that have been measured by the biconical antenna 43, and FIG. 13 shows the results of the emission measurement from 300 MHz to 1 GHz, that have been measured by the log periodic antenna 45.

The horizontal axis of each graph represents the frequency, and the vertical axis represents the power level expressing the radiation intensity of the measurement cable. Further, the measurement result of the comparison cable 40a is marked “#1”, the measurement result of the comparison cable 40b is marked “#2”, and the measurement result of the cable 100 is marked “#3”. Furthermore, the measurement in the case where the antenna direction is horizontal is marked “Horizontal”, and the measurement in the case where the antenna direction is vertical is marked “Vertical”.

First, with reference to FIG. 12, the results of the emission measurement from 30 MHz to 300 MHz will be described.

As shown on the top row of FIG. 12, when the antenna direction is horizontal, the radiation intensity of the comparison cable 40a is roughly −70 dBm or more across the entire measurement range, and includes a peak exceeding −50 dBm. It is noted that when the antenna direction is vertical, the radiation intensity of the comparison cable 40a is roughly −80 dBm or less across the entire measurement range, which is smaller than that of the horizontal case.

As shown on the middle row of FIG. 12, when the antenna direction is horizontal, the radiation intensity of the comparison cable 40b is −70 dBm or less across the entire measurement range. On the other hand, when the antenna direction is vertical, the radiation intensity of the comparison cable 40a may become-70 dBm or more.

As shown on the bottom row of FIG. 12, when the antenna direction is horizontal, the radiation intensity of the cable 100 to which the present technology is applied is roughly −80 dBm or less on a low low frequency side of the measurement range, and is −70 dBm or less across the entire measurement range even in the case of a high radiation intensity. Further, when the antenna direction is vertical, the radiation intensity of the cable 100 is about −80 dBm at most. In other words, it can be said that in the range from 30 MHz to 300 MHz, the radiation intensity of the cable 100 to which the present technology is applied is sufficiently suppressed as compared to those of the comparison cable 40a and the comparison cable 40b.

Next, the results of the emission measurement from 300 MHz to 1 GHz will be described with reference to FIG. 13.

As shown on the top row of FIG. 13, when the antenna direction is horizontal, the radiation intensity of the comparison cable 40a includes a plurality of peaks exceeding −70 dBm across the entire measurement range, and a peak exceeding −60 dBm is also measured on the low frequency side. It is noted that when the antenna direction is vertical, the radiation intensity of the comparison cable 40a is smaller than that of the horizontal case and is −80 dBm or less except for the low frequency side of the measurement range.

As shown on the middle row of FIG. 13, when the antenna direction is horizontal, the radiation intensity of the comparison cable 40b includes peaks exceeding −70 dBm on the high frequency side, but is −70 dBm or less on the low frequency side, and does not have peaks exceeding −60 dBm as seen in the comparison cable 40a. It is noted that similar to the horizontal case, the case where the antenna direction is vertical also shows a larger radiation intensity than the comparison cable 40a.

As shown on the bottom row of FIG. 13, when the antenna direction is horizontal, the radiation intensity of the cable 100 to which the present technology is applied is smaller than that of the comparison cable 40b on the low frequency side of the measurement range, and is comparable with that of the comparison cable 40b on the high frequency side. Further, when the antenna direction is vertical, the radiation intensity of the cable 100 is comparable with that of the comparison cable 40a, and is smaller than that of the comparison cable 40b. In other words, it can be said that even in the range from 300 MHz to 1 GHz, the radiation intensity of the cable 100 to which the present technology is applied is sufficiently suppressed as compared to those of the comparison cable 40a and the comparison cable 40b.

### [Immunity Measurement]

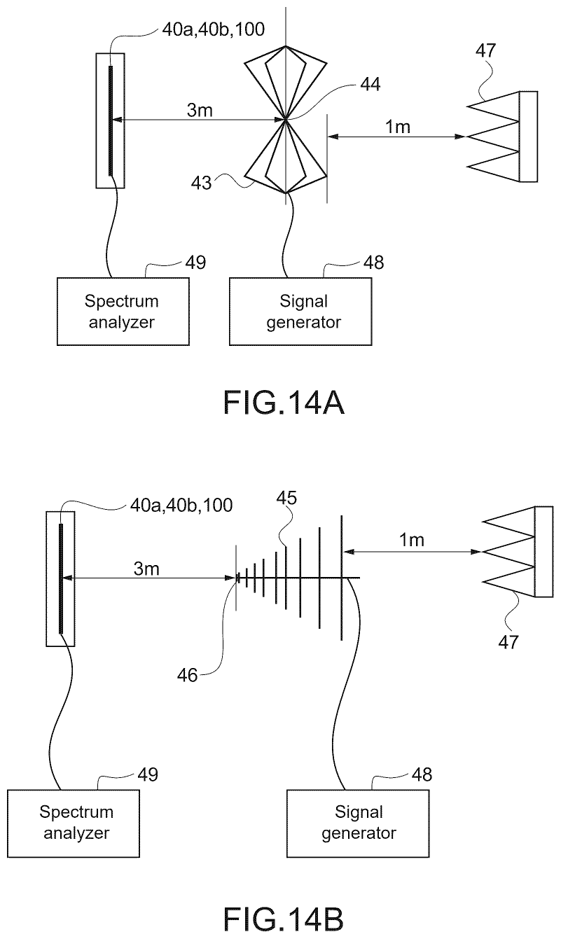

FIGS. 14A and 14B are schematic diagrams each showing an example of the immunity measurement. FIG. 14A is a diagram showing an example of arrangement of the immunity measurement that uses the biconical antenna 43, and FIG. 14B is a diagram showing an example of arrangement of the immunity measurement that uses the log periodic antenna 45.

The arrangement of the measurement cables (the comparison cable 40a, the comparison cable 40b, and the cable 100) and the antennas (the biconical antenna 43 and the log periodic antenna 45) in the immunity measurement is similar to that in the emission measurement.

It is noted that one end of the measurement cable was connected to the spectrum analyzer, and the other end of the measurement cable was terminated at 50Ω. In addition, the biconical antenna 43 and the log periodic antenna 45 were connected to the signal generator 48.

In the immunity measurement, a signal of 10 dBm was output from the signal generator 48 while sweeping the frequency, and this signal was applied to the biconical antenna 43 and the log periodic antenna 45. At this time, the power level of the measurement cable was measured using the spectrum analyzer 49. Hereinafter, the power level of the measurement cable may be referred to as a reception intensity of the measurement cable.

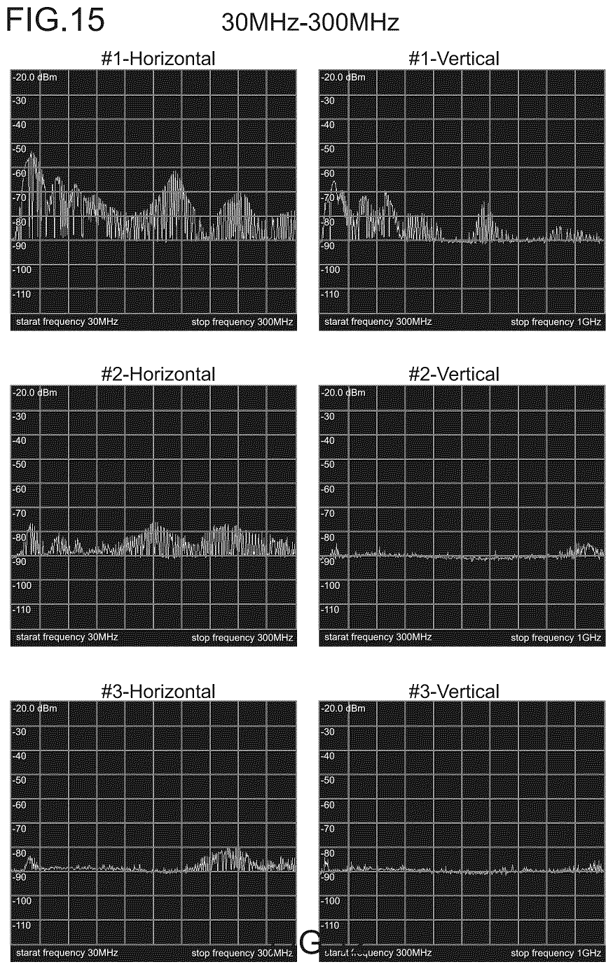

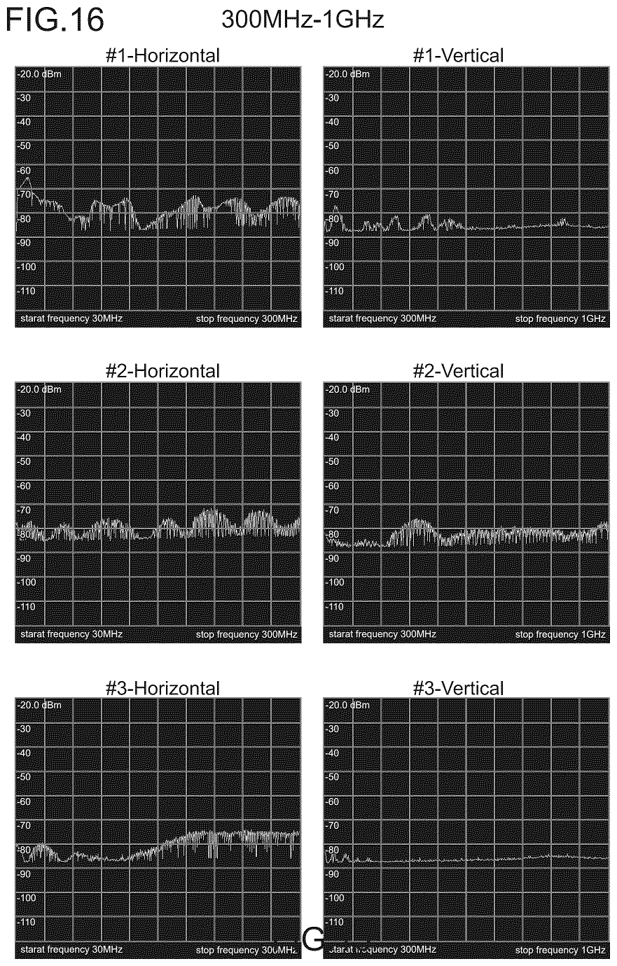

FIGS. 15 and 16 are graphs showing the measurement results of the immunity measurement. FIG. 15 shows the results of the immunity measurement when signals of 30 MHz to 300 MHz are input to the biconical antenna 43, and FIG. 16 shows the results of the immunity measurement when signals of 300 MHz to 1 GHz are input to the log periodic antenna 45. The horizontal axis of each graph represents the frequency, and the vertical axis represents the power level expressing the reception intensity of the measurement cable.

First, with reference to FIG. 15, the results of the immunity measurement from 30 MHz to 300 MHz will be described.

As shown on the top row of FIG. 15, when the antenna direction is horizontal, the reception intensity of the comparison cable 40a is roughly-80 dBm or more across the entire measurement range, and a peak exceeding −60 dBm is also measured. Further, when the antenna direction is vertical, the reception intensity of the comparison cable 40a includes peaks exceeding −70 dBm and peaks exceeding −80 dBm.

As shown on the middle row of FIG. 15, when the antenna direction is horizontal, the reception intensity of the comparison cable 40b includes a plurality of peaks exceeding −80 dBm, but is lower than that of the comparison cable 40a as a whole. Furthermore, when the antenna direction is vertical, the reception intensity of the comparison cable 40b is roughly-90 dBm.

As shown on the bottom row of FIG. 15, when the antenna direction is horizontal, the reception intensity of the cable 100 to which the present technology is applied is roughly −90 dBm on the low frequency side of the measurement range, and is about −80 dBm at most on the high frequency side. Further, when the antenna direction is vertical, the reception intensity of the cable 100 is roughly-90 dBm across the entire measurement range. In other words, it can be said that in the range from 30 MHz to 300 MHz, the reception intensity of the cable 100 to which the present technology is applied is sufficiently suppressed as compared to those of the comparison cable 40a and the comparison cable 40b.

Next, the results of the immunity measurement from 300 MHz to 1 GHz will be described with reference to FIG. 16.

As shown on the top row of FIG. 16, when the antenna direction is horizontal, the reception intensity of the comparison cable 40a includes a plurality of peaks exceeding −80 dBm across the entire measurement range, and a peak exceeding −70 dBm is also measured on the low frequency side. It is noted that when the antenna direction is vertical, the reception intensity of the comparison cable 40a has a plurality of peaks of about −80 dBm.

As shown on the middle row of FIG. 16, when the antenna direction is horizontal, the reception intensity of the comparison cable 40b includes a plurality of peaks exceeding −80 dBm similar to the comparison cable 40a, but there is no peak exceeding −70 dBm as seen on the low frequency side of the comparison cable 40a. Further, when the antenna direction is vertical, the reception intensity of the comparison cable 40b is roughly-80 dBm across the entire measurement range, which is larger than the reception intensity of the comparison cable 40a.

As shown on the bottom row of FIG. 16, when the antenna direction is horizontal, the reception intensity of the cable 100 to which the present technology is applied is roughly −80 dBm or less on the low frequency side of the measurement range, and is comparable with those of the comparison cable 40a and the comparison cable 40b on the high frequency side. Further, when the antenna direction is vertical, the reception intensity of the cable 100 is −80 dBm or less across the entire measurement range, and there are no peaks included in the comparison cable 40a and the comparison cable 40b. In other words, it can be said that even in the range from 300 MHz to 1 GHz, the reception intensity of the cable 100 to which the present technology is applied is sufficiently suppressed as compared to those of the comparison cable 40a and the comparison cable 40b.

In this manner, looking at the measurement results of both cases where the antenna direction is horizontal and vertical, the radiation intensity and reception intensity of the cable 100 are much smaller than those of the comparison cable 40a which is a normal coaxial cable. In addition, the radiation intensity and reception intensity of the cable 100 are also sufficiently reduced as compared to those of the comparison cable 40b wound with two layers of magnetic resins. In other words, it has become clear in the emission measurement and the immunity measurement that the cable 100 to which the present technology is applied is capable of exerting extremely high noise resistance performance.

As described above, in the cable 100 according to the present embodiment, the magnetic tape 20 wound around the transmission portion 10 is covered by the magnetic resin layer 30. Accordingly, the intrusion and radiation of noise are effectively reduced by the magnetic tape 20 having relatively high magnetic permeability. Furthermore, by covering the magnetic tape 20 by the magnetic resin layer, the shield performance is maintained even when a gap or the like is generated in the magnetic tape 20 due to bending. As a result, it becomes possible to realize a cable that suppresses the intrusion and radiation of noise and is less likely to deteriorate in performance even when bent.

When a magnetic shield of a cable is formed using a magnetic resin, ferrite or the like as the magnetic material is dispersed in a synthetic resin that is a base material of the magnetic resin. Therefore, the magnetic flux is cut off by the synthetic resin in the magnetic resin, making it difficult to raise the magnetic permeability, and thus the effect as the magnetic shield cannot be sufficiently improved. It is noted that since the magnetic resin can hermetically cover the entire transmission portion that is to become the core of the cable, the performance will not deteriorate largely.

It is also possible to form the magnetic shield of the cable using only the magnetic tape. For example, a magnetic tape that realizes high magnetic permeability has also been developed, where the high magnetic permeability is realized by forming a magnetic layer on a surface of a tape material by application or vapor deposition in a state in which the orientation is aligned, the tape material containing metal such as aluminum. Such a magnetic tape is used in a USB cable and the like. Meanwhile, although the magnetic tape has high magnetic permeability, if a gap is generated, noise may enter from the gap or be radiated from the gap so as to lower the effect as the magnetic shield.

In the cable 100 according to the present embodiment, the circumference of the magnetic tape 20 is covered by the magnetic resin layer 30. That is, the cable 100 has a configuration in which the tape coated with the magnetic material is covered by a resin in which the magnetic material is dispersed. By winding the magnetic tape 20 and then covering the magnetic tape 20 by the magnetic resin layer 30 in this manner, noise will not leak from the gaps in the magnetic tape 20. In addition, since the magnetic fluxes are coupled by the magnetic resin layer 30 at the gaps of the magnetic tape 20, it becomes possible to realize a magnetic shield that exerts the high magnetic permeability of the magnetic tape 20 throughout the cable 100.

For example, since the magnetic permeability is high, the high frequency impedance becomes high, and thus it becomes possible to significantly reduce the conductive noise that the cable 100 receives from an apparatus connected thereto. In addition, since noise does not leak from the gaps of the magnetic tape 20, it also becomes possible to significantly reduce the spatial noise (radiation noise) radiated from the cable 100 (see FIGS. 12 and 13). For similar reasons, it is also possible to significantly reduce the spatial noise that enters from the gaps in the cable 100 (see FIGS. 15 and 16).

Furthermore, if the magnetic shield is formed using only the magnetic tape 20, when the cable 100 is bent, the gaps of the magnetic tape 20 may become large to cause deterioration of the shield performance. In contrast, since the cable 100 is provided with the magnetic resin layer 30 on the circumference of the magnetic tape 20, even if the gaps of the magnetic tape 20 become large due to bending, the magnetic flux is less likely to be cut off, and the shield performance is less likely to deteriorate. Therefore, even when the cable 100 is bent, it becomes possible to sufficiently suppress the high frequency current that flows through the cable 100.

Furthermore, in the magnetic tape 20, by aligning the orientation of the magnetic material, high magnetic permeability can be realized without increasing the thickness of the magnetic layer 24. This makes it possible to realize a thin magnetic tape 20. As a result, it is possible to make the diameter of the cable 100 sufficiently smaller than that of the case where the magnetic resin layer is provided doubly as in the comparison cable 40b described above, for example. By the thin magnetic tape 20, it is possible to realize a diameter that is almost the same as that of a conventional cable that is not provided with the magnetic shield like the comparison cable 40a, for example.

Moreover, the magnetic tape 20 can be formed by transverse winding and can be formed without impairing the flexibility of the cable 100. This makes it possible to realize a cable 100 that is highly flexible and easy to handle and does not deteriorate in performance due to bending.

### OTHER EMBODIMENTS

The present technology is not limited to the embodiment described above, and various other embodiments can be realized. In the embodiment described above, the magnetic layer 24 is provided on both sides (the inner side and the outer side) of the tape base material 21 in the magnetic tape 20. However, without being limited to this, the magnetic layer 24 may be formed on one side of the tape base material 21.

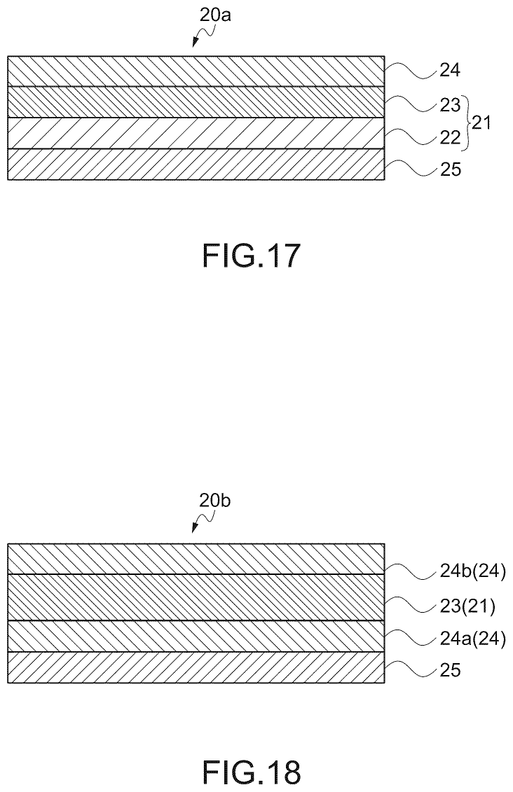

FIG. 17 is a schematic diagram showing another configuration example of the magnetic tape. In a magnetic tape 20a shown in FIG. 17, the magnetic layer 24 is formed on one surface of the tape base material 21.

The magnetic tape 20a includes the adhesive layer 25, the resin base material 22, the metal layer 23, and the magnetic layer 24 in the stated order from the inner side. Of these, the resin base material 22 and the metal layer 23 are included in the tape base material 21. That is, in the magnetic tape 20a, the adhesive layer 25 is formed on the inner side of the tape base material 21 (the inner side of the resin base material 22), and the magnetic layer 24 is formed on the outer side of the tape base material 21 (the outer side of the metal layer 23). In this manner, it can be said that the magnetic tape 20a has a configuration in which the inner magnetic layer 24a is eliminated and only the outer magnetic layer 24b remains in the magnetic tape 20 that has been described with reference to FIG. 3A and the like.

The magnetic tape 20a is wound around the transmission portion 10 (see FIG. 3A and the like) with the magnetic layer 24 on the outer side. The magnetic tape 20a is typically wound transversely. Further, the circumference of the magnetic tape 20a wound around the transmission portion 10 is covered by the magnetic resin layer 30. In this manner, by forming the magnetic layer 24 on the side of the tape base material 21 that faces the outer side, the magnetic flux is not cut off at a portion corresponding to the gap of the magnetic tape 20, and the performance as the magnetic shield can be significantly improved.

It is noted that it is also possible to use a magnetic tape in which the magnetic layer 24 is formed only on the inner side of the tape base material 21. Even in this case, conductive noise transmitted through the cable can be sufficiently suppressed by the magnetic layer 24 having high magnetic permeability, for example. In addition, since the magnetic resin layer 30 formed on the outer side of the magnetic layer 24 also functions as the magnetic shield, spatial noise that enters from outside the cable can be sufficiently attenuated, for example.

In the embodiment described above, as the tape base material 21, the descriptions have been given on the tape-like member in which the metal layer 23 is formed on the resin base material 22. However, the present technology is not limited to this, and a tape base material 21 that is formed of metal and does not include the resin base material 22 may be used instead. FIG. 18 is a schematic diagram showing another configuration example of the magnetic tape. In a magnetic tape 20b shown in FIG. 18, the tape base material 21 is a metal tape that includes a metal foil formed of one of aluminum, copper, and iron.

The magnetic tape 20b includes the adhesive layer 25, the inner magnetic layer 24a, the metal layer 23, and the outer magnetic layer 24b in the stated order from the inner side. Of these, the metal layer 23 is a metal tape that includes a metal foil and is the tape base material 21 of the magnetic tape 20b. That is, in the magnetic tape 20b, the magnetic layers 24 (the inner magnetic layer 24a and the outer magnetic layer 24b) are formed on both sides of the metal tape base material 21 (metal layer 23) that has been formed without using the resin base material or the like. In this manner, it can be said that the magnetic tape 20b has a configuration in which the resin base material 22 is eliminated from the magnetic tape 20 that has been described with reference to FIG. 3A and the like.

The metal tape base material 21 (metal layer 23) itself functions as an electric field shield, and is therefore capable of reflecting, for example, the electric field components of spatial noise that enters from outside the cable. As a result, in the magnetic tape 20b, it is possible to make the overall thickness of the tape thinner while maintaining the shield performance, compared to, for example, the magnetic tape 20 shown in FIG. 3A.

In the embodiment described above, in the magnetic tape, the adhesive layer is provided on the innermost side of the magnetic tape. However, the present technology is not limited to this, and the adhesive layer may be provided on the outermost side of the magnetic tape. Alternatively, the magnetic tape may be used with the inner and outer sides of the magnetic tape described above reversed. That is, the magnetic tape may be used such that the adhesive layer is arranged on the outermost side. In this case, for example, the magnetic tape is wound transversely such that parts of the magnetic tape partially overlap. At this time, the magnetic tapes on the inner and outer sides are bonded to each other at the overlapping portions. Even with such a configuration, it is possible to exert high shield performance by providing the magnetic resin layer on the outer side of the magnetic tape.

In addition, the metal layer does not need to be provided in the tape base material of the magnetic tape. That is, the resin base material may be used alone as the tape base material, and the oriented magnetic layer may be formed on both sides (or one side) of the resin base material. In this case, although the magnetic tape loses its function as the electric field shield, it is possible to configure an effective magnetic shield by the magnetic layer having high magnetic permeability. It is also possible to eliminate the adhesive layer of the magnetic tape.

The descriptions above have mainly been given on the case where the magnetic tape is wound transversely with respect to the transmission portion of the cable such that parts of the magnetic tape overlap in the width direction. The way to wind the magnetic tape is not limited to this.

The magnetic tape may alternatively be wound transversely by other methods.

For example, the magnetic tape may be wound transversely around the transmission portion such that the side end surfaces come into contact with each other. That is, the magnetic tape may be wound spirally such that parts of the magnetic tape do not overlap in the width direction and no gap is formed between the side end surfaces of the magnetic tape. In this case, for example, a gap may be formed between the side end surfaces of the magnetic tape due to bending, but by covering the magnetic tape with the magnetic resin layer, it becomes difficult for the magnetic flux to be cut off between the side end surfaces, and deterioration of the shield performance can be suppressed.

Alternatively, for example, the magnetic tape may be wound transversely around the transmission portion such that a gap is formed between the side end surfaces. In this case, a usage amount of the magnetic tape is reduced, making it possible to reduce the material cost of the cable. It is noted that since the gap between the side end surfaces is filled with the magnetic resin layer, it is possible to make the magnetic flux difficult to be cut off.

Alternatively, the magnetic tape may be wound longitudinally. When the magnetic tape is wound longitudinally, the magnetic tape is wound tightly on the surface of the transmission portion such that the extension direction of the magnetic tape coincides with the extension direction of the transmission portion.

For example, the magnetic tape may be wound longitudinally around the transmission portion such that the side end surfaces overlap in the width direction. Accordingly, the transmission portion can be completely covered by the magnetic tape.

Alternatively, for example, the magnetic tape may be wound longitudinally such that the side end surfaces thereof come into contact with each other and the transmission portion is covered. That is, the magnetic tape may be wound to enclose the transmission portion such that parts of the magnetic tape do not overlap in the width direction and no gap is formed between the side end surfaces of the magnetic tape. Even in this case, by covering the magnetic tape by the magnetic resin layer, the magnetic flux is less likely to be cut off at the gaps or the like that are formed between the side end surfaces due to bending of the cable, and deterioration of the shield performance can be suppressed.

Alternatively, for example, the magnetic tape may be wound longitudinally around the transmission portion such that a gap is formed between the side end surfaces. Even in this case, since the gap between the side end surfaces is filled with the magnetic resin layer, it is possible to make the magnetic flux difficult to be cut off.

In the embodiment described above, the configuration in which the magnetic resin layer directly covers the magnetic tape has been mainly described. However, the present technology is not limited to this, and an intermediate layer may be formed between the magnetic tape and the magnetic resin layer. The intermediate layer is, for example, a resin layer for improving adhesion of the magnetic resin layer with respect to the magnetic tape. In this case, for example, when the cable is bent, a gap is less likely to be generated between the magnetic tape and the magnetic resin layer, and deterioration of the shield performance due to bending can be suppressed.

In addition, the type of the intermediate layer is not limited. Further, a thickness of the intermediate layer is set to a thickness that allows the magnetic resin layer to exert the function of connecting the magnetic fluxes at the gap of the magnetic tape, for example. Accordingly, the shield performance of the cable can be improved.

In the descriptions above, the embodiment in which the present technology is applied to the coaxial cable has been mainly described. The present technology can also be applied to cables other than the coaxial cable. Hereinafter, the cables to which the present technology is applied will be described.

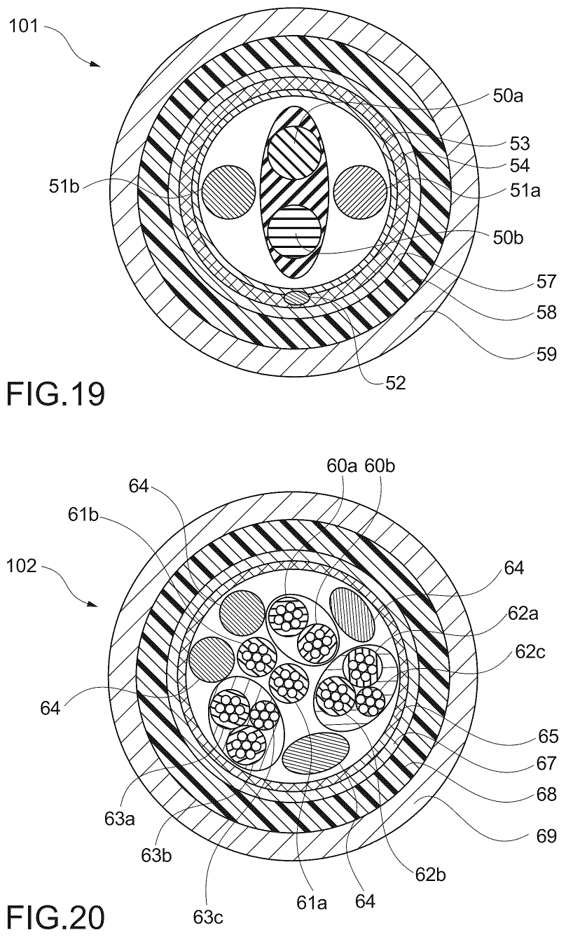

FIG. 19 is a cross-sectional view of a USB 2.0 cable. A cable 101 shown in FIG. 19 includes five wires: a pair of signal cables 50a (D−) and 50b (D+) for differential transmission, power supply cables 51a and 51b, and a drain wire 52 as a ground wire. In each of the signal cables 50a and 50b and the power supply cables 51a and 51b, a circumference of a core wire is covered by an insulating coating film.

Copper is used as the core wire, and either a single wire that includes a single conductive wire or a twisted wire in which a single conductive wire is obtained by twisting thin conductive wires together may be used. The signal cables 50a and 50b are twisted pair cables. The signal cables 50a and 50b and the power supply cables 51a and 51b are covered by an aluminum foil shield 53 and a copper wire mesh shield 54 in the stated order from the inner side. Further, the drain wire 52 and the aluminum foil shield 53 are electrically connected.

When the present technology is applied to the USB 2.0 cable 101, a magnetic tape 57 is wound around the copper wire mesh shield 54, and a magnetic resin layer 58 that covers the magnetic tape 57 is formed around the magnetic tape 57. In addition, an outer cover layer 59 that becomes an outermost layer is provided around the magnetic resin layer 58. The USB 2.0 cable 101 to which the present technology is applied can suppress noise and can suppress deterioration in performance due to bending.

FIG. 20 is a cross-sectional view of a USB 3.0 cable. A cable 102 shown in FIG. 20 includes four wires: a pair of signal cables 60a and 60b for differential transmission and power supply cables 61a and 61b, similar to the USB 2.0 cable 101. The signal cables 60a and 60b are called UTP (Unshielded Twisted Pair). Furthermore, the cable 102 includes USB 3.0 signal cables 62a and 62b and a drain wire 62c, and other USB 3.0 signal lines 63a and 63b and a drain wire 63c. The signal cables 62a and 62b are called SDP (Shielded Differential Pair). A filler 64 is used as an option. These wires and the filler are covered by a copper wire mesh shield 65.

When the present technology is applied to the USB 3.0 cable 102, a magnetic tape 67 is wound around the copper wire mesh shield 65, and a magnetic resin layer 68 that covers the magnetic tape 67 is formed around the magnetic tape 67. In addition, an outer cover layer 69 that becomes an outermost layer is provided around the magnetic resin layer 68. The USB 3.0 cable 102 to which the present technology is applied can suppress noise and can suppress deterioration in performance due to bending.

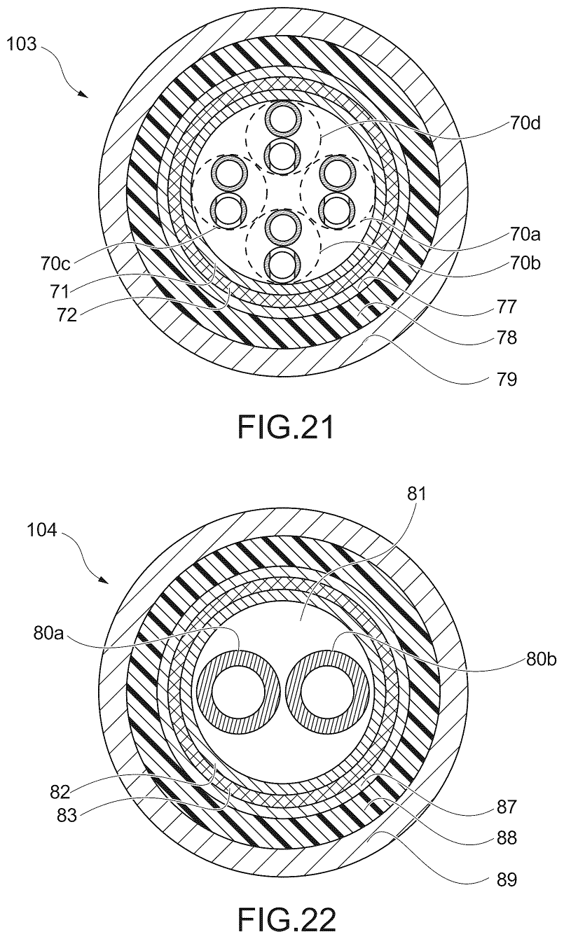

FIG. 21 is a cross-sectional view of an Ethernet cable (LAN cable). In a LAN cable 103 shown in FIG. 21, four pairs of signal lines 70a, 70b, 70c, and 70d each having a twisted pair cable configuration are covered by a shield. The shield is obtained by stacking a conductor sheet 71 formed of a PET base material with thin aluminum and a braided wire 72 from the inner side.

When the present technology is applied to the LAN cable 103, a magnetic tape 77 is wound around the braided wire 72, and a magnetic resin layer 78 that covers the magnetic tape 77 is formed around the magnetic tape 77. In addition, an outer cover layer 79 that becomes an outermost layer is provided around the magnetic resin layer 78. The LAN cable 103 to which the present technology is applied can suppress noise and can suppress deterioration in performance due to bending.

FIG. 22 is a cross-sectional view of a duplex cable. A duplex cable 104 shown in FIG. 22 includes two transmission lines 80a and 80b. The duplex cable 104 is a signal cable, and the transmission lines 80a and 80b are signal transmission lines. Alternatively, the duplex cable 104 is a power supply cable, and the transmission lines 80a and 80b function as a hot line and a ground line. The duplex cable 104 has a shield configuration similar to that of the cable 100 shown in FIGS. 3A and 3B. That is, the outer side of the transmission lines 80a and 80b is covered by an insulator 81, and a shield layer that includes a conductor sheet 82 and a braided wire 83 in the stated order from the inner side is formed around the insulator 81. It is noted that the insulator 81 may be a resin or a fiber thread such as a cotton thread for making a cross section of the duplex cable 104 circular.

When the present technology is applied to the duplex cable 104, a magnetic tape 87 is wound around the braided wire 83, and a magnetic resin layer 88 that covers the magnetic tape 87 is formed around the magnetic tape 87. In addition, an outer cover layer 89 that becomes an outermost layer is provided around the magnetic resin layer 88. The duplex cable 104 to which the present technology is applied can suppress noise and can suppress deterioration in performance due to bending. Furthermore, although the magnetic tape 87 is formed on the shield layer including the conductor sheet 82 and the braided wire 83 in FIG. 22, it is also possible to eliminate the shield layer.

In addition, the cable according to the present technology may be configured as any one of a signal cable, a power cable, or an in-vehicle cable. For example, the coaxial cable 100, the USB 2.0 cable 101, the USB 3.0 cable 102, the LAN cable 103, and the duplex cable 104 described above are each an example of the signal cable. Moreover, the duplex cable 104 described above is also an example of the power cable.

Further, in the examples described above, the magnetic tape is wound around the shield layer exemplified by the copper wire mesh shield 54, the copper wire mesh shield 65, the braided wire 72, and the braided wire 83, but it is also possible to wind the magnetic tape directly around each cable or around a cable in which a cross section is made circular by a filler or an insulator.

Moreover, the cable according to the present technology is mounted on an apparatus that requires noise resistance performance, such as an automobile, for example, and is configured as an in-vehicle cable that connects devices and sensors of the automobile. By applying the present technology as described above, it is possible to suppress the conductive noise that propagates through the cable and the spatial noise that enters the cable, and also suppress deterioration in performance due to bending. This makes it possible to easily design the layout of each cable without worrying about the influence of noise among the cables, for example. In addition, since the deterioration in performance due to bending is small, handling and installation of the cable can be performed with ease.

Of the feature portions according to the present technology described above, at least two of the feature portions can be combined. In other words, the various feature portions described in the respective embodiments may be arbitrarily combined without distinction of the embodiments. Moreover, the various effects described above are mere examples and are not limited, and other effects may also be exerted.

In the present disclosure, the terms “same”, “equal”, “orthogonal”, and the like are concepts including “substantially the same”, “substantially equal”, “substantially orthogonal”, and the like. For example, a state within a predetermined range (e.g., range within +10%) that uses “completely the same”, “completely equal”, “completely orthogonal”, and the like as a reference is also included.

It is noted that the present technology can also take the following configurations.

(1) A cable, including:
a transmission portion including at least one transmission line that transmits a signal or power;
a magnetic tape including a magnetic layer that absorbs radio waves, the magnetic tape being wound around the transmission portion; and
a magnetic resin layer that is formed of a magnetic resin that absorbs radio waves, the magnetic resin layer covering the magnetic tape.
   (2) The cable according to (1), in which
the magnetic tape includes a tape base material on which the magnetic layer is formed, and
the magnetic layer is formed on one of two sides of the tape base material or both of the two sides.
   (3) The cable according to (2), in which
the magnetic layer is formed on at least one of the two sides of the tape base material that faces an outer side of the magnetic tape.
   (4) The cable according to (2) or (3), in which
the tape base material is a resin tape formed of a polyester-based resin or a polyolefin-based resin.
   (5) The cable according to any one of (2) to (4), in which
the tape base material is a resin tape in which a metal layer formed of one of aluminum, copper, and iron is formed.
   (6) The cable according to any one of (2) to (5), in which
the tape base material is a metal tape that includes a metal foil formed of one of aluminum, copper, and iron.
   (7) The cable according to any one of (2) to (6), in which
the magnetic layer is a coating layer of a magnetic material that is applied on a surface of the tape base material such that the magnetic material is oriented.
   (8) The cable according to any one of (2) to (7), in which
the magnetic layer is a deposited film of a magnetic material or a sputtered film of the magnetic material, the deposited film or sputtered film being formed on a surface of the tape base material.
   (9) The cable according to any one of (1) to (8), in which
the magnetic tape is wound transversely around the transmission portion.
   (10) The cable according to (9), in which
the magnetic tape is wound transversely around the transmission portion such that parts of the magnetic tape overlap in a width direction.
   (11) The cable according to any one of (1) to (10), in which
the transmission portion includes a shield layer surrounding the at least one transmission line, and
the magnetic tape is wound around the shield layer.
   (12) The cable according to any one of (1) to (11), in which
the magnetic tape includes an adhesive layer formed on a side of the magnetic tape that faces the transmission portion.
   (13) The cable according to any one of (1) to (12), in which
the magnetic layer contains a magnetic material that includes at least one of iron powder, ferrite powder, or carbon powder.
   (14) The cable according to any one of (1) to (13), in which
the magnetic resin includes a synthetic resin that is a base material, and a magnetic material that includes at least one of iron powder, ferrite powder, or carbon powder.
   (15) The cable according to (14), in which
the magnetic resin contains the iron powder or the ferrite powder, and
a proportion of the iron powder or ferrite powder contained in the magnetic resin is 70% or more and 90% or less by weight in the magnetic resin.
   (16) The cable according to any one of (1) to (15), further including:

an insulating outer cover layer that covers a circumference of the magnetic resin layer.

(17) The cable according to any one of (1) to (16), in which
the cable is one of a coaxial cable, a USB cable, a signal cable, a power cable, and an in-vehicle cable.
   (18) A cable manufacturing method, including:
forming a transmission portion including at least one transmission line that transmits a signal or power;
winding, around the transmission portion, a magnetic tape including a magnetic layer that absorbs radio waves; and
forming a magnetic resin layer by applying, onto the magnetic tape, a magnetic resin that absorbs radio waves.
   (19) The cable manufacturing method according to (18), in which
the magnetic resin layer is a resin coating formed by extruding the magnetic resin onto an intermediate body obtained by winding the magnetic tape around the transmission portion.

### REFERENCE SIGNS LIST

10 transmission portion
20, 20a, 20b, 57, 67, 77, 87 magnetic tape
21 tape base material
22 resin base material
23 metal layer
24 magnetic layer
24a inner magnetic layer
24b outer magnetic layer
25 adhesive layer
30, 58, 68, 78, 88 magnetic resin layer
33, 59, 69, 79, 89 outer cover layer
100, 101, 102 cable
103 LAN cable
104 duplex cable

1. A cable, comprising:
a transmission portion including at least one transmission line that transmits a signal or power;
a magnetic tape including a magnetic layer that absorbs radio waves, the magnetic tape being wound around the transmission portion; and
a magnetic resin layer that is formed of a magnetic resin that absorbs radio waves, the magnetic resin layer covering the magnetic tape.

2. The cable according to claim 1, wherein
the magnetic tape includes a tape base material on which the magnetic layer is formed, and
the magnetic layer is formed on one of two sides of the tape base material or both of the two sides.

3. The cable according to claim 2, wherein
the magnetic layer is formed on at least one of the two sides of the tape base material that faces an outer side of the magnetic tape.

4. The cable according to claim 2, wherein
the tape base material is a resin tape formed of a polyester-based resin or a polyolefin-based resin.

5. The cable according to claim 2, wherein
the tape base material is a resin tape in which a metal layer formed of one of aluminum, copper, and iron is formed.

6. The cable according to claim 2, wherein
the tape base material is a metal tape that includes a metal foil formed of one of aluminum, copper, and iron.

7. The cable according to claim 2, wherein
the magnetic layer is a coating layer of a magnetic material that is applied on a surface of the tape base material such that the magnetic material is oriented.

8. The cable according to claim 2, wherein
the magnetic layer is a deposited film of a magnetic material or a sputtered film of the magnetic material, the deposited film or sputtered film being formed on a surface of the tape base material.

9. The cable according to claim 1, wherein
the magnetic tape is wound transversely around the transmission portion.

10. The cable according to claim 9, wherein
the magnetic tape is wound transversely around the transmission portion such that parts of the magnetic tape overlap in a width direction.

11. The cable according to claim 1, wherein
the transmission portion includes a shield layer surrounding the at least one transmission line, and
the magnetic tape is wound around the shield layer.

12. The cable according to claim 1, wherein
the magnetic tape includes an adhesive layer formed on a side of the magnetic tape that faces the transmission portion.

13. The cable according to claim 1, wherein
the magnetic layer contains a magnetic material that includes at least one of iron powder, ferrite powder, or carbon powder.

14. The cable according to claim 1, wherein
the magnetic resin includes a synthetic resin that is a base material, and a magnetic material that includes at least one of iron powder, ferrite powder, or carbon powder.

15. The cable according to claim 14, wherein
the magnetic resin contains the iron powder or the ferrite powder, and
a proportion of the iron powder or ferrite powder contained in the magnetic resin is 70% or more and 90% or less by weight in the magnetic resin.

16. The cable according to claim 1, further comprising:
an insulating outer cover layer that covers a circumference of the magnetic resin layer.

17. The cable according to claim 1, wherein
the cable is one of a coaxial cable, a USB cable, a signal cable, a power cable, and an in-vehicle cable.

18. A cable manufacturing method, comprising:
forming a transmission portion including at least one transmission line that transmits a signal or power;
winding, around the transmission portion, a magnetic tape including a magnetic layer that absorbs radio waves; and
forming a magnetic resin layer by applying, onto the magnetic tape, a magnetic resin that absorbs radio waves.

19. The cable manufacturing method according to claim 18, wherein
the magnetic resin layer is a resin coating formed by extruding the magnetic resin onto an intermediate body obtained by winding the magnetic tape around the transmission portion.
